(19) United States
(12) Patent Application Publication
(10) Pub. No.: US 2025/0267834 A1
(43) Pub. Date: Aug. 21, 2025

(54) MEMORY CELL STRUCTURES WITH GATE-CUT FEATURES ON CELL BOUNDARIES

(71) Applicant: Taiwan Semiconductor Manufacturing Company, Ltd., Hsin-Chu (TW)

(72) Inventor: Jhon Jhy Liaw, Hsinchu County (TW)

(21) Appl. No.: 18/582,953

(22) Filed: Feb. 21, 2024

(51) Int. Cl. H10B 10/00

(52) U.S. Cl. CPC H10B 10/125

(57) ABSTRACT

One aspect of the present disclosure pertains to a memory structure. The memory structure includes multiple memory cells, each of the memory cells includes two active regions extending lengthwise along a first direction and four gate structures extending lengthwise along a second direction perpendicular to the first direction. Each of the four gate structures extend across channel regions of the two active regions. The memory structure further includes a pair of gate-cut dielectric features extending lengthwise along the first direction at cell boundaries between each of the memory cells, each of the gate-cut dielectric features contacts the each of the four gate structures in each of the memory cells.

### BACKGROUND

The electronics industry has experienced an ever-increasing demand for smaller and faster electronic devices that are simultaneously able to support a greater number of increasingly complex and sophisticated functions. To meet these demands, there is a continuing trend in the integrated circuit (IC) industry to manufacture low-cost, high-performance, and low-power ICs. Thus far, these goals have been achieved in large part by reducing IC dimensions (for example, minimum IC feature size), thereby improving production efficiency and lowering associated costs. However, such scaling has also increased complexity of the IC manufacturing processes. Thus, realizing continued advances in IC devices and their performance requires similar advances in IC manufacturing processes and technology.

As technology nodes become smaller, uniformity control of active regions becomes an issue across adjacent cells (e.g., across adjacent static random access memory (SRAM) cells) and across adjacent devices (e.g., across adjacent n-type transistor devices and/or adjacent p-type transistor devices). For example, when forming fin active regions for finFET or gate-all-around transistors, if the fin active layout is non-regular (e.g., short fin length, random dense/isolate fin space, irregular fin end shape), there results in poor performance and worse device matching. In SRAM cell layouts, there is a risk of non-regular fin active layout due to the pull-up transistors requiring discontinued active regions to prevent leakages between adjacent SRAM cells. Having discontinued active regions may cause performance issues due to poor isolation and/or irregular fin end shape between the discontinued active regions. Further, there may also be unintended bridging or merging between source/drain epitaxial features of different adjacent devices due to inadequate and non-uniform isolation.

Therefore, although existing structures and methods for implementing memory cell structure layouts have been generally adequate for their intended purposes, they have not been entirely satisfactory in every aspect.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. It is also emphasized that the drawings appended illustrate only typical embodiments of this invention and are therefore not to be considered limiting in scope, for the invention may apply equally well to other embodiments. Further, the accompanying figures may implicitly describe features not explicitly described in the detailed description.

FIG. 1 illustrates an SRAM array having a plurality of memory cells and bit lines, bit line bars, and word lines each extending over the memory cells, according to an embodiment of the present disclosure.

FIG. 2 illustrates a circuit diagram of an SRAM array having a plurality of memory cells, according to an embodiment of the present disclosure.

FIGS. 3, 4A, 4B, 5A, and 5B illustrate top view device layouts of an SRAM array such as the SRAM array in FIG. 1 and corresponding to the circuit diagram of FIG. 2, according to an embodiment of the present disclosure.

FIG. 6 illustrates a top view device layout of an SRAM array having two adjacent memory cells, according to an embodiment of the present disclosure.

FIG. 7A illustrates a cross-sectional view of an SRAM array cut along the line A in FIG. 6, according to an embodiment of the present disclosure.

FIG. 7B illustrates a cross-sectional view of an SRAM array cut along the line B in FIG. 6, according to an embodiment of the present disclosure.

FIGS. 7C-1 and 7C-2 illustrate cross-sectional views of an SRAM array cut along the line C in FIG. 6, according to an embodiment of the present disclosure.

FIGS. 7D-1 and 7D-2 illustrate cross-sectional views of an SRAM array cut along the line D in FIG. 6, according to an embodiment of the present disclosure.

FIGS. 7E-1 and 7E-2 illustrate cross-sectional views of an SRAM array cut along the line E in FIG. 6, according to an embodiment of the present disclosure.

FIGS. 7F-1 and 7F-2 illustrate cross-sectional views of an SRAM array cut along the line F in FIG. 6, according to an embodiment of the present disclosure.

FIG. 7G illustrates a cross-sectional view of an SRAM array cut along the line G in FIG. 6, according to an embodiment of the present disclosure.

FIG. 7H illustrates a cross-sectional view of an SRAM array cut along the line H in FIG. 6, according to an embodiment of the present disclosure.

FIG. 8 illustrates a top view device layout of an SRAM array having two adjacent memory cells, according to another embodiment of the present disclosure.

FIG. 8I illustrates a cross-sectional view of an SRAM array cut along the line I in FIG. 8, according to an embodiment of the present disclosure.

FIG. 8J illustrates a cross-sectional view of an SRAM array cut along the line J in FIG. 8, according to an embodiment of the present disclosure.

FIGS. 9, 10, 11, and 12 illustrate top view device layouts of SRAM arrays corresponding to the circuit diagram of FIG. 2, according to additional embodiments of the present disclosure.

FIG. 13 illustrates a method of forming an SRAM array structure having gate-end dielectric lines, according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “under,” “below,” “lower,” “above,” “over,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Still further, when a number or a range of numbers is described with “about,” “approximate,” “substantially,” and the like, the term is intended to encompass numbers that are within a reasonable range including the number described, such as within +/−10% of the number described, or other values as understood by person skilled in the art. For example, the term “about 5 nm” may encompass the dimension range from 4.5 nm to 5.5 nm where manufacturing tolerances associated with depositing the material layer are known to be +/−10% by one of ordinary skill in the art. And when comparing a dimension or size of a feature to another feature, the phrases “substantially the same,” “essentially the same,” “of similar size,” and the like, may be understood to be within +/−10% between the compared features. Further, disclosed dimensions of the different features can implicitly disclose dimension ratios between the different features.

The present disclosure relates to memory devices and structures, and particularly to memory structures having gate-cut dielectric lines on memory cell boundaries and shared bit line and bit line bars across adjacent memory cells. The memory structures may implement an array of static random-access memory (SRAM) cells. The gate-cut dielectric lines and the shared bit line and bit line bars provide benefits to cell performance. For example, the gate-cut (or gate-end) dielectric lines prevents unintended bridging or merging between source/drain (S/D) epitaxial features of different adjacent memory devices. Further, the gate-cut dielectric lines provide proper isolation between active regions of different memory cells, thereby solving line end shrink concerns when forming discontinuous active regions. Further, the gate-cut dielectric lines allow forming smaller gate end space between gates of different memory cells due to having a dedicated gate cut region. Further, the shared bit line and bit line bar design merges two memory cells with a bit line pair and a bit line bar pair to allow implementation of wider bit lines and bit line bars for larger memory arrays or allow larger metal space for other metal features to reduce parasitic capacitance. The present disclosure includes other layout improvements such as having dielectric gate portions to isolate pull-up transistors, extra gate-cut features to prevent stray coupling, and various placement of local interconnects, bit lines, bit line bars, and word lines, that further improve cell performance and uniformity control.

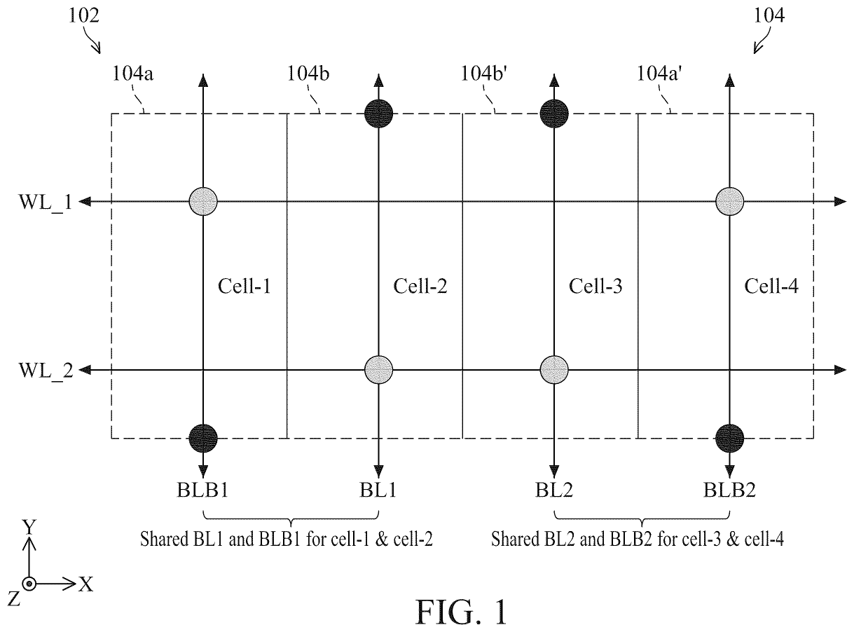

FIG. 1 illustrates an SRAM array 102 having a plurality of SRAM memory cells 104 adjacent to each other along the x direction. The memory cells 104 may include memory cells 104a, 104b, 104b′, and 104a′. As an example, memory cell 104a corresponds to cell-1, memory cell 104b corresponds to cell-2, memory cell 104b′ corresponds to cell-3, and memory cell 104a′corresponds to cell-4. As shown, cell-1 shares a vertical cell boundary along the y direction with cell-2, cell-2 shares a vertical cell boundary along the y direction with cell-3, and cell-3 shares a vertical cell boundary along the y direction with cell-4. Although not shown, the SRAM array 102 may include additional memory cells 104. For example, additional memory cells 104 may be adjacent the top and/or bottom horizontal cell boundaries (x direction) of cell-1 to cell-4. For another example, additional memory cells 104 may be adjacent vertical cell boundaries (y direction) of cell-1 and/or cell-4.

Still referring to FIG. 1, the SRAM array 102 includes a first pair of bit signal lines for cell-1 and cell-2 (i.e., bit line BL1 and bit line bar BLB1). Cell-1 and cell-2 share the same bit line BL1 and the same bit line bar BLB1. The bit line BL1 extends lengthwise along the y direction across cell-2, and the bit line bar BLB1 extends lengthwise along the y direction across cell-1. The bit line BL1 may land on a via connection that is on a top edge boundary of cell-2. The bit line bar BLB1 may land on a via connection that is on a bottom edge boundary of cell-1.

The SRAM array 102 further includes a second pair of bit signal lines for cell-3 and cell-4 (i.e., bit line BL2 and bit line bar BLB2). Cell-3 and cell-4 share the same bit line BL2 and the same bit line bar BLB2. The bit line BL2 extends lengthwise along the y direction across cell-3, and the bit line bar BLB2 extends lengthwise along the y direction across cell-4. The bit line BL2 may land on a via connection that is on a top edge boundary of cell-3. The bit line bar BLB2 may land on a via connection that is on a bottom edge boundary of cell-4.

The SRAM array 102 further includes a first word line WL_1 and a second word line WL_2 extending across cell-1 to cell-4. In the embodiment shown, cell-1 and cell-4 share the same word line WL_1, and cell-2 and cell-3 share the same word line WL_2. For example, the word line WL_1 may land on via connections within cell-1 and cell-4, and the word line WL_2 may land on via connections within cell-2 and cell-3.

Still referring to FIG. 1, the word lines WL_1 and WL_2 may continuously extend in the x direction across additional memory cells 104 not shown, each word line WL_1 and WL_2 connecting to different sets memory cells 104. The bit lines and bit line bars BL1, BL2, BLB1, and BLB2 may also continuously extend in the y direction across additional memory cells 104 not shown, each bit line and bit line bars BL1, BL2, BLB1, and BLB2 connecting to different pairs of memory cells 104. In an embodiment, for every two adjacent memory cells 104 (e.g., memory cells 104a and 104b), there may be a pair of shared bit signal lines (e.g., BL1 and BLB1 is shared for cell-1 and cell-2).

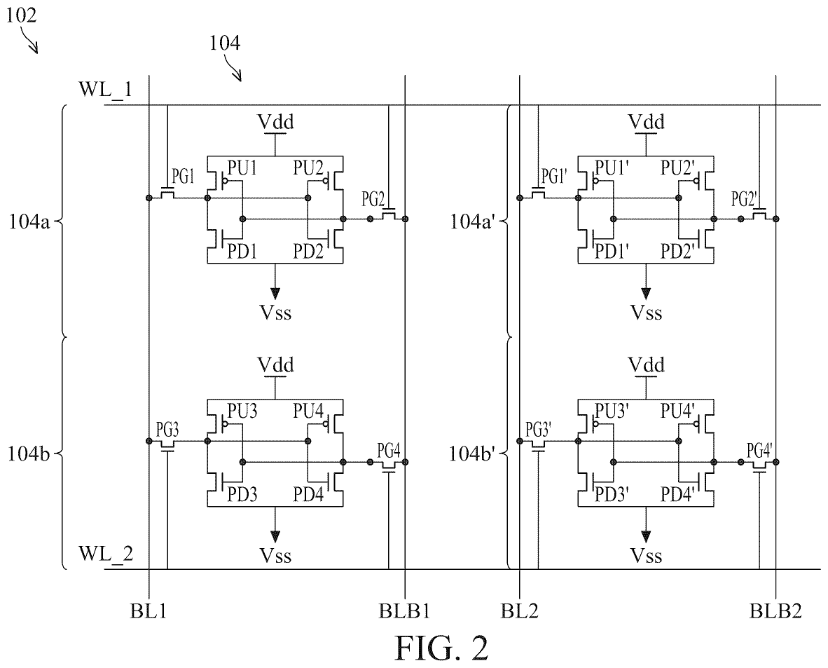

FIG. 2 illustrates a circuit diagram of an SRAM array 102 having a plurality of memory cells 104. In the present embodiment, the circuit diagram corresponds to an SRAM array 102 of four memory cells 104 (also referred herein as SRAM cells 104). The circuit diagram is consistent with and may depict the SRAM array 102 in FIG. 1. As shown, the SRAM array 102 includes SRAM cells 104a, 104a′, 104b, and 104b′. Each of the SRAM cells 104a, 104a′, 104b, and 104b′ is formed of six transistors (two pull-down transistors, two pull-up transistors, and two pass-gate transistors). Each transistor is defined by a source, a drain, and a gate. Each SRAM cell 104 stores a bit of memory through the pull-down and pull-up transistors, and the SRAM cells are addressed by word lines and bit lines through the pass-gate transistors.

The SRAM cell 104a includes pull-up transistors PU1 and PU2, pull-down transistors PD1 and PD2, and pass gate transistors PG1 and PG2. The sources of PU1 and PU2 are coupled together and connected to high voltage Vdd. The sources of PD1 and PD2 are coupled together and connected to low source voltage Vss or ground. The gates of PU1 and PD1 are coupled together and connected to the common drains of PU2, PD2 and PG2. The gates of PU2 and PD2 are coupled together and connected to the common drains of PU1, PD1, and PG1. PU1, PU2, PD1, and PD2 form a first set of cross coupled inverters to store a data bit. The source of PG1 is connected to a first bit line BL1 and the source of PG2 is connected to a first bit line bar BLB1. The gates of PG1 and PG2 are connected to a first word line WL_1.

The SRAM cell 104b includes pull-up transistors PU3 and PU4, pull-down transistors PD3 and PD4, and pass gate transistors PG3 and PG4. The sources of PU3 and PU4 are coupled together and connected to high voltage Vdd. The sources of PD3 and PD4 are coupled together and connected to low voltage Vss or ground. The gates of PU3 and PD3 are coupled together and connected to the common drains of PU4, PD4 and PG4. The gates of PU4 and PD4 are coupled together and connected to the common drains of PU3, PD3, and PG3. PU3, PU4, PD3, and PD4 form a second set of cross coupled inverters to store a data bit. The source of PG3 is connected to the same first bit line BL1 and the source of PG4 is connected to the same first bit line bar BLB1. The gates of PG3 and PG4 are connected to a second word line WL_2.

The SRAM cells 104a′ and 104b′ are configured similarly to the respective SRAM cells 104a and 104b. The SRAM cells 104a′ includes pull-up transistors PU1′ and PU2′, pull-down transistors PD1′ and PD2′, and pass gate transistors PG1′ and PG2′. The SRAM cell 104b′ includes pull-up transistors PU3′ and PU4′, pull-down transistors PD3′ and PD4′, and pass gate transistors PG3′ and PG4′. For the sake of brevity, similar configurations and connections will not be repeated. The SRAM cells 104a′ and 104b′ include a third and fourth set of cross coupled inverters that each store a data bit. The sources of PG1′ and PG3′ are connected to a second bit line BL2. The sources of PG2′ and PG4′ are connected to a second bit line bar BLB2. The SRAM cell 104a′ share the same first word line WL_1 with the SRAM cell 104a, and the SRAM cell 104b′ share the same second word line WL_B with the SRAM cell 104b. That is, the gates of the pass-gate transistors PG1′ and PG2′ also connect to the first word line WL_1, and the gates of the pass-gate transistors PG3′ and PG4′ also connect to the second word line WL_2.

Note that FIG. 2 shows an example embodiment of an SRAM array, but other configurations may be possible. For example, in other embodiments, source and drain nodes of the different pull-up and pull-down transistors may be flipped. Further, the Vdd and Vss nodes may also be flipped. In other words, in some embodiments, high voltage Vdd may connect to source or to drain in any of the pull-up and pull-down transistors of the SRAM array. And in other embodiments, low voltage Vss or ground may connect to source or to drain in any of the pull-up and pull-down transistors of the SRAM array. As such, electrical connections to Vdd and to Vss are herein referred to as power lines, power signal lines, or power line connections that provide routing to power pull-up and pull-down transistors in the memory cells 104.

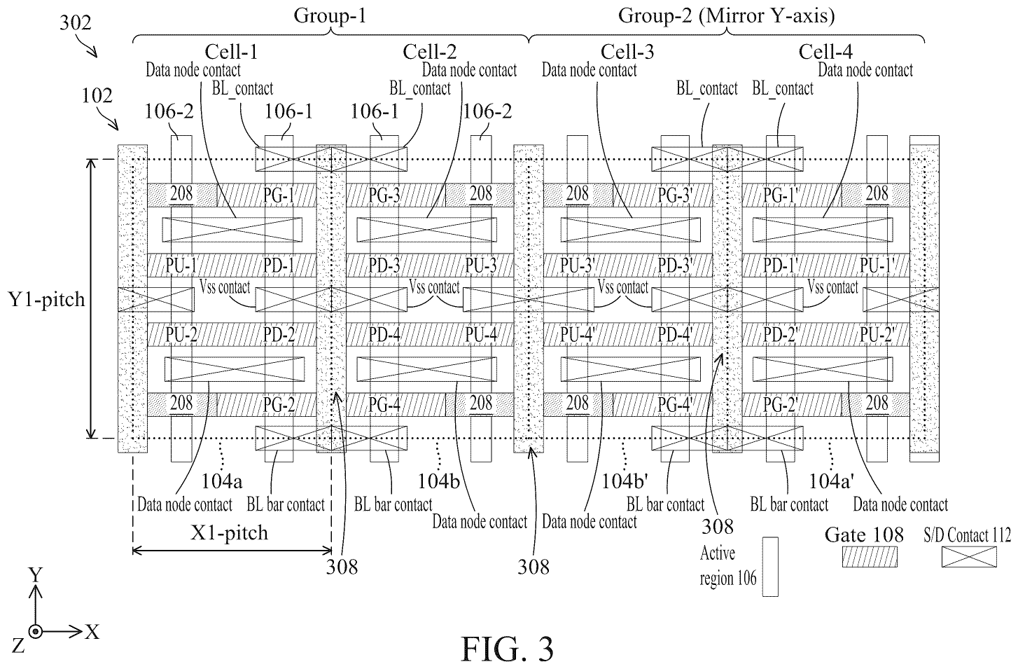

FIG. 3 illustrates a top view device layout 302 of an SRAM array 102, such as the SRAM array 102 in FIG. 1 and corresponding to the circuit diagram of FIG. 2. The device layout 302 represents portions of a memory structure having various semiconductor features as described herein. As shown, the device layout 302 includes the SRAM cells 104a, 104b, 104b′, and 104a′ defined by the dashed line cell boundaries. The SRAM cells 104a, 104b, 104b′, and 104a′ may correspond to the SRAM cells 104a, 104b, 104b′, and 104a′ in FIG. 2.

The SRAM cells 104a and 104b are adjacent to each other in the x direction and mirror each other across a vertical cell boundary between them. The SRAM cells 104b′ and 104a′ are adjacent to each other in the x direction and mirror each other across a vertical cell boundary between them. SRAM cells 104a and 104b, which correspond to cell-1 and cell-2 part of group-1, share a first pair of bit line signal contacts (i.e., BL and BL bar contacts). SRAM cells 104b′ and 104a′, which correspond to cell-3 and cell-4 part of group-2, share a second pair of bit line signal contacts (i.e., BL and BL bar contacts). Further, as shown by the positions of the different transistors (PD-1, PD-2, . . . , etc.), group-2 mirrors group-1 across the y axis (e.g., PU-3 mirror PU-3′, PD-3 mirrors PD-3′, and so on).

FIG. 3 shows where each of the transistors PU1, PU1′, PU2, PU2′, PU3, PU3′, PU4, PU4′, PD1, PD1′, PD2, PD2′, PD3, PD3′, PD4, PD4′, PG1, PG1′, PG2, PG2′, PG3, PG3′, PG4, and PG4′ are located (labeled on the gate 108 of each transistor). How each transistor is connected to each other has already been described with respect to FIG. 2 and will not be repeated here for the sake of brevity. Note that each of these transistors are formed and defined by respective channel regions of the active regions 106 under respective gates 108 and S/D regions having epitaxial features adjacent the channel regions.

The device layout 302 includes several active regions 106 extending along the y direction. The active regions 106 may be configured for planar, fin, or gate-all-around semiconductor structures. In an embodiment, the active regions 106 are fin structures that protrude in the positive z direction from a base substrate. The active regions 106 may include n-type active regions 106-1 for forming pull-down and pass-gate transistors (e.g., PG-1, PD-1, PD-2, and PG-2) and p-type active regions 106-2 for forming pull-up transistors (e.g., PU-1 and PU-2). The p-type active regions 106-2 are discontinuous and extend shorter along the y direction than the n-type active regions 106-1. As shown, the p-type active regions 106-2 are segmented due to separation cuts by dielectric gate portions 208 of gates 108. As such, the p-type active regions 106-2 at most span a length that is less than a height of an SRAM cell 104 along the y direction. On the other hand, the n-type active regions 106-1 may span continuously in the y direction across multiple SRAM cells 104. In some embodiments, like as shown, the n-type active regions 106-1 may be wider in the x direction than the p-type active regions 106-2.

The device layout 302 includes several gates 108 disposed over channel regions of the active regions 106. The channel regions (or transistor channels) refer to portions of the active region 106 directly under a gate 108. Adjacent the channel regions (e.g., between gates 108 along the y direction) are S/D regions of the active regions 106. The S/D regions and may refer to a source or a drain, individually or collectively dependent upon the context. For n-type active regions 106-1, the S/D regions may include epitaxial features doped with n-type dopants such as phosphorous or arsenic. For p-type active regions 106-2, the S/D regions may include epitaxial features doped with p-type dopants such as boron. The epitaxial features may be grown from a semiconductor material using a suitable epitaxial growth technique.

The gates 108 extend lengthwise in the x direction and are discontinuous due to separation cuts by gate-cut dielectric lines 308 extending lengthwise along the y direction. The gates 108 are gate structures that include metal gates (also referred to as metal gate portions), and in some cases also include dielectric gates 208 (also referred to as dielectric gate portions 208). In each memory cell 104, two the gates 108 include metal gates (or metal gate portions) that span continuously between gate-cut dielectric lines 308. The metal gates may include gate spacers surrounding gate stacks, and the gate stacks may include a gate electrode over a gate dielectric. In each memory cell 104, another two of the gates 108 include metal gates (or metal gate portions) and dielectric gates 208 (or dielectric gate portions 208) that together span continuously between gate-cut dielectric lines 308. Specifically, the dielectric gate portions 208 are incorporated in gates 108 that sandwich the pull-up transistors (e.g., PU-1 and PU-2) in the y direction. The dielectric gate portions 208 cut through channel regions of p-type active regions 106-2 to isolate pull-up devices in one SRAM cell 104 from pull-up devices in adjacent SRAM cells 104 (in the y direction). By incorporating the dielectric gate portions 208, the p-type active regions 106-2 may be first formed continuously like the n-type active regions 106-1. Thereafter, the p-type active regions 106-2 are cut for isolation when forming gates 108. Thereafter, dielectric gate portions 208 are formed in the cut area. This process solves the line end shrink concerns when forming discontinuous active regions 106.

The device layout 302 includes gate-cut dielectric lines 308 disposed along vertical cell boundaries of SRAM cells 104. The gate-cut dielectric lines 308 may also be referred herein as gate-cut dielectric features, gate-end dielectric lines, or gate end cut structures. The gate-cut dielectric lines 308 are in direct contact with side surfaces of the gates 108. The gate-cut dielectric lines 308 extends continuously along the y direction and cuts through the gates 108 that extends along the y direction, thereby forming isolated gates 108 self-contained in respective SRAM cells 104a. In other words, the gates 108 in one SRAM cell 104 (e.g., SRAM cell 104a) is isolated and separated from the gates 108 in an adjacent SRAM cell (e.g., SRAM cell 104b) by the gate-cut dielectric lines 308. Further, the gate-cut dielectric lines 308 also cut through any overgrowth S/D features growing from S/D regions of the active regions 106, and the S/D features in one SRAM cell 104 (e.g., SRAM cell 104a) is also isolated and separated from the S/D features in an adjacent SRAM cell (e.g., SRAM cell 104b) by the gate-cut dielectric lines 308. In this way, the continuous gate-cut dielectric lines 308 prevents S/D epitaxial overgrowth bridging (or merging) concern and allow the S/D features to maximize epitaxial size (e.g., touch and stop at the gate-cut dielectric lines 308). As such, the S/D regions in n-type active regions 106-1 may be enlarged to have more volume for S/D resistance reduction (SiP, SiPC for NMOSFET), and the S/D regions in p-type active regions 106-2 may be enlarged to have more volume for strain layer (SiGe for PMOSFET), thereby benefiting overall cell performance. Even further, by having a clearly defined gate cut isolation, the gate-cut dielectric lines 308 also allow for forming smaller gate end space with excellent gate critical dimension uniformity control. In an embodiment, the gate to gate end isolation may range from 3 nm to 20 nm (e.g., width of the gate-cut dielectric lines 308 in the x direction).

In the embodiment shown, each SRAM cell 104 is defined by two active regions 106 (i.e., an n-type active region 106-1 and a p-type active region 106-2) and four gates 108 extending over the two active regions 106. The n-type active region 106-1 and the respective gates 108 form two pass-gate transistors that sandwich two pull-down transistors along the y direction. The p-type active region 106-2 and the respective gates 108 form two dielectric gate portions 208 that sandwich pull-up transistors along the y direction. For example, in each cell, the top and bottom gates 108 along the y direction are gates 108 having dielectric gate portions 208, as well as metal gate portions for pass-gate transistors (e.g., PG-1 and PG-2). And in each cell, the middle gates 108 along the y direction are gates 108 having only metal gate portions for pull-down and pull-up transistors (e.g., shared gate 108 for PD-1 and PU1 and shared gate 108 for PD-2 and PU-2). Further, each SRAM cell 104 is defined by gate-cut dielectric lines 308 disposed along vertical cell boundaries of SRAM cells 104. In other words, each SRAM cell 104 spans between two gate-cut dielectric lines 308. Note also that like the metal portions of gates 108, the dielectric gate portions 208 may extend to directly contact side surfaces of the gate-cut dielectric lines 308.

Still referring to FIG. 3, each SRAM cell 104 is defined by a cell height (i.e., y1-pitch) along the y direction and a cell width (i.e., x1-pitch) along the x direction, and the cell height is greater than the cell width. The cell height (i.e., y1-pitch) is a distance substantially equal to four times a distance between respective center lines of two adjacent cell gates 108 along the y direction. The cell width (i.e., x1-pitch) is a distance between respective center lines of two adjacent gate-cut dielectric lines 308 along the x. In an embodiment, a ratio between the cell height to the cell width is in a range of between about 1.2 to 2.6.

Still referring to FIG. 3, the device layout 302 further includes S/D contacts 112 over S/D regions of the active regions 106. The S/D contacts 112 may be metal contacts (e.g., tungsten) that land on S/D epitaxial features in the S/D regions of the active regions 106. As shown, the S/D contacts 112 may be shared slot contacts that extend lengthwise along the x direction to land on multiple S/D regions of different transistors. The S/D contacts may include (1) node contacts such as data node contacts and data node bar contacts that connect common drains of pull-down, pull-up, and pass-gate transistors together, (2) power line contacts such as Vss contacts and Vdd contacts to connect common sources of respective pull-down and pull-up transistors together, and (3) bit signal line contacts such as BL contacts and BL bar contacts that connect common sources of respective pass-gate transistors together. For every two adjacent memory cell 104 (e.g., cell-1 and cell-2 or cell-3 and cell-4), there is a shared BL contact and a shared BL bar contact that extend across vertical cell boundaries. As shown, the BL contacts and BL bar contacts may extend over and also land on a top surface of the gate-cut dielectric lines 308. Also as shown, the Vss and Vdd contacts may also extend over and land on a top surface of the gate-cut dielectric lines 308.

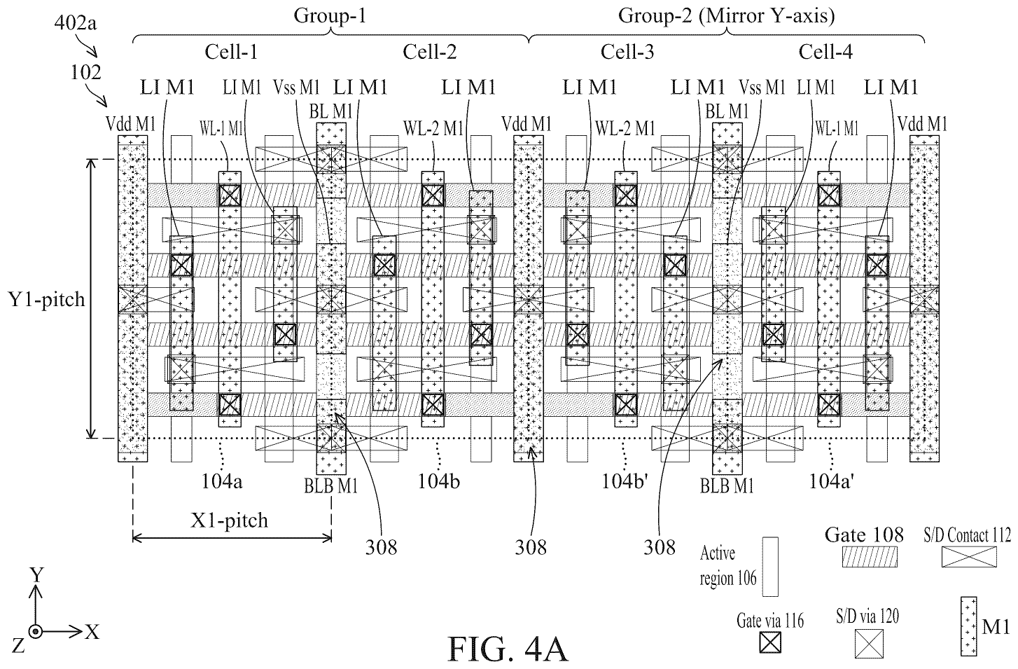

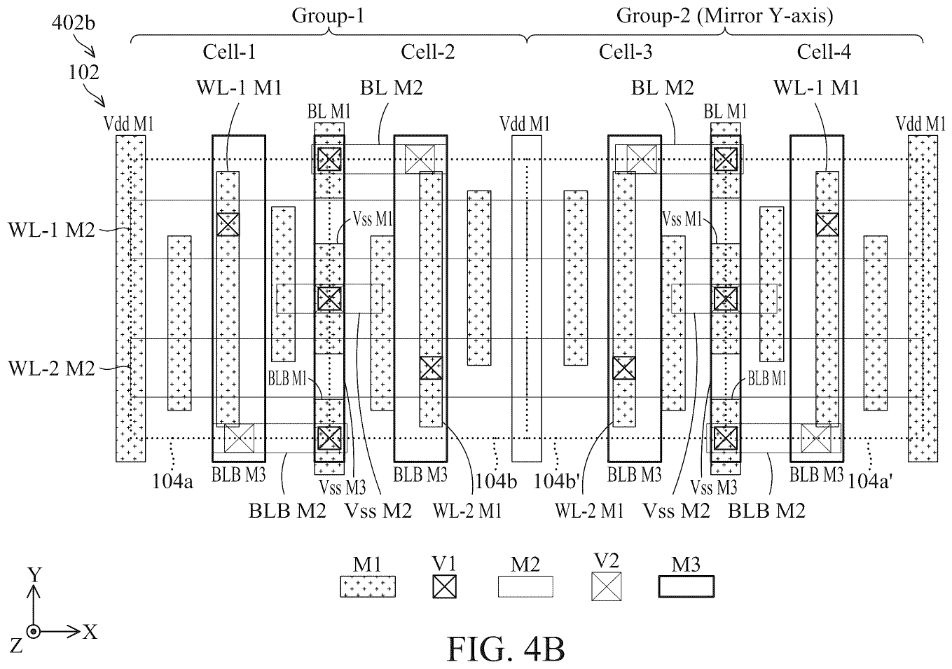

FIG. 4A illustrates a top view device layout 402a of an SRAM array 102, such as the SRAM array 102 in FIG. 1 and corresponding to the circuit diagram of FIG. 2. The device layout 402a represents portions of a memory structure having various semiconductor features as described herein. FIG. 4A corresponds to FIG. 3, and the similar features will not be repeated for the sake of brevity. The difference is that FIG. 4A further shows gate vias 116, S/D vias 120, and first metal lines M1. The gate vias 116 land on gates 108 (or metal gate portions thereof). The S/D vias 120 land on S/D contacts 112. And the first metal lines M1 land on the gate vias 116 and/or the S/D vias 120. The gate vias 116 and S/D vias 120 route respective gates 108 and S/D contacts 112 to a higher material layer (e.g., a first metal layer having first metal lines M1). As shown, the first metal lines M1 include local connection lines LI M1, word line landing pads WL-1 M1 and WL-2 M2, bit line and bit line bar landing pads BL M1 and BLB M1, and Vdd and Vss landing pads Vdd M1 and Vss M1. In the embodiment shown, each SRAM cell 104 includes two local connection lines LI M1, one of them electrically connects a data-node contact of an S/D contact 112 with a gate 108 and another one of them electrically connects a data-node bar contact of an S/D contact 112 with another gate 108. Each SRAM cell 104 includes a word line landing pad WL-1 M1 or WL-1 M2 located between the two local connection lines LI M1 along the x direction. Each of the word line landing pad WL-1 M1 and WL-1 M2 lands on two gate vias 116 connected to pass-gate transistors. At the vertical cell boundaries of the SRAM cells 104, there are bit line landing pads BL M1, bit line bar landing pads BLB M1, Vdd landing pads Vdd M1, and Vss landing pads Vss M1. Each of these landing pads lands on an S/D via 120 and provide a landing area for routing their respective nodes (e.g., bit line, bit line bar, Vdd, and Vss) to a higher material layer (e.g., a second metal layer having second metal lines M2). In the embodiment shown, at one vertical cell boundary, there is a Vdd landing pad Vdd M1 every two x1-pitches, and at an opposing vertical cell boundary, there is a bit line landing pad BL M1, a bit line bar landing pad BLB M1, and a Vss landing pad Vss M1 every two x-1 pitches.

FIG. 4B illustrates a top view device layout 402b of an SRAM array 102, such as the SRAM array 102 in FIG. 1 and corresponding to the circuit diagram of FIG. 2. The device layout 402b represents portions of a memory structure having various semiconductor features as described herein. FIG. 4B corresponds to FIG. 4A, and the similar features will not be repeated for the sake of brevity. The difference is that FIG. 4B only shows the first metal lines M1 from FIG. 4A while the features disposed under it are filtered out for ease of view. FIG. 4B further shows first vias V1 landing on the first metal lines M1, second metal lines M2 landing on the first vias V1, second vias V2 landing on the second metal lines M2, and third metal lines M2 landing on the second vias V2. The first vias V1 route respective first metal lines M1 to a higher material layer (e.g., a second metal layer having second metal lines M2). The second vias V2 route respective second metal lines M2 to a higher material layer (e.g., a third metal layer having third metal lines M3). As shown, the second metal lines M2 include word line metals WL-1 M2 and WL-2 M2. The word line metals WL-1 M2 and WL-2 M2 are global word lines that each continuously extend lengthwise along the x direction across a row of multiple SRAM cells 104. Each memory cell 104 includes the word line metals WL-1 M2 and WL-2 M2 extending across them. Each of the word line metals WL-1 M2 and WL-2 M2 electrically connect gates 108 of pass-gate transistors in different memory cells 104 together. Note that each of the word line metals WL-1 M2 and WL-2 M2 connect to different sets of memory cells 104.

Still referring to FIG. 4B, as shown, the second metal lines M2 further include Vss landing pads Vss M2, bit line landing pads BL M2, and bit line bar landing pads BLB M2. Each of these landing pads lands on a first via V1 and provide a landing area for routing their respective nodes (e.g., Vss, bit line, and bit line bar) to a higher material layer (e.g., a third metal layer having third metal lines M3). As shown, the third metal lines M3 include bit line metals BL M3 and bit line bar metals BLB M3. WL-2 M2. The bit line metals BL M3 and bit line bar metals BLB M3 are global bit lines and bit line bars that each continuously extend lengthwise along the y direction across a column of multiple SRAM cells 104. In the present embodiment, each memory cell 104 only includes one bit line metal BL M3 or one bit line bar metal BLB M3 extending across them, each of which routes the bit lines or bit line bars of two adjacent SRAM cells 104. The third metal lines M3 further include Vss metals (e.g., Vss M3) that continuously extend lengthwise along the y direction at vertical cell boundaries. Each Vss metals (e.g., Vss M3) is disposed between a bit line metal BL M3 and a bit line bar metal BLB M3 along the x direction.

Still referring to FIG. 4B, the layout design for sharing adjacent bit lines and bit line bars, and the strategic placement of the first metal lines M1, the second metal lines M2, and the third metal lines M3, each allow for improved cell performance. For example, the layout design allows more room to implement wider bit line metals BL M3 and bit line bar metals BLB M3, or to implement larger spacing between the bit line metals BL M3 and bit line bar metals BLB M3 to reduce parasitic capacitance. In the present embodiments, the global bit lines and bit line bars are moved from the first metal layer having the first metal lines M1 to the third metal layer having third metal lines M3, thereby freeing up space in both the first metal layer and the third metal layer. In the present embodiment, the global bit lines and bit line bars (e.g., in the third metal layer) are disposed above the global word lines (e.g., in the second metal layer).

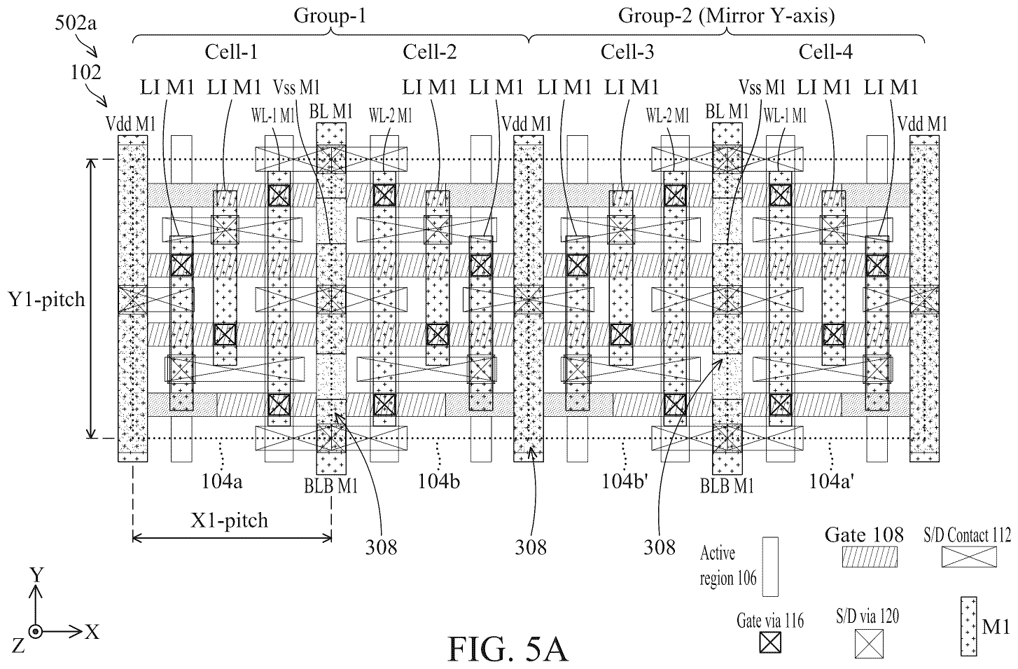

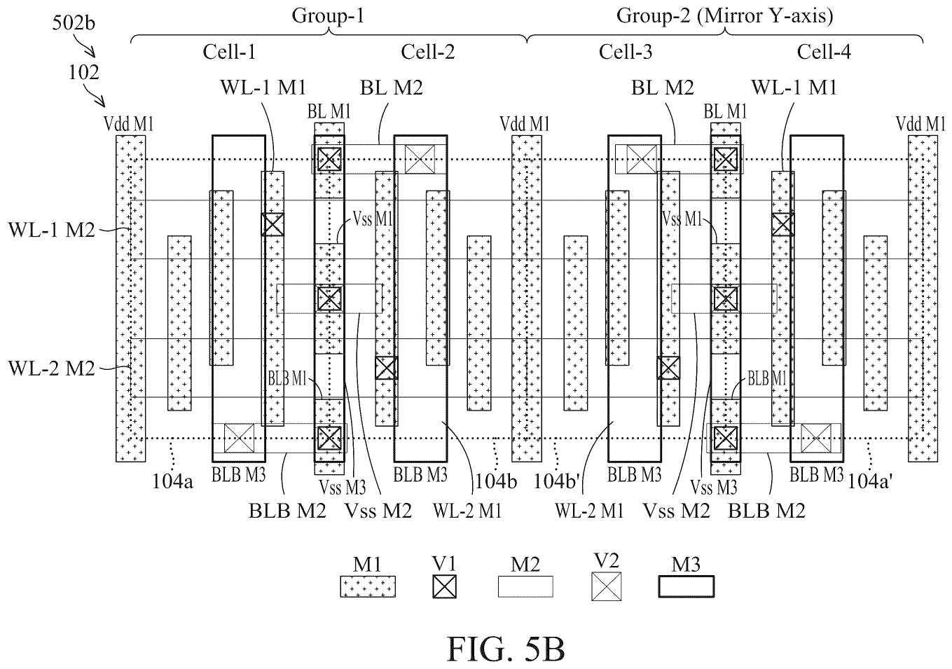

FIGS. 5A-5B illustrate top view device layouts 502a and 502b of an SRAM array 102, such as the SRAM array 102 in FIG. 1 and corresponding to the circuit diagram of FIG. 2. The device layouts 502a and 502b represents portions of a memory structure having various semiconductor features as described herein. FIGS. 5A-5B is similar to FIG. 4A-4B, respectively, and the similar features will not be repeated for the sake of brevity. The difference is that FIGS. 5A-5B show an embodiment with a different layout configuration for the first metal lines M1. As shown in FIGS. 5A-5B, the word line landing pad WL-1 M1 or WL-1 M2 in each SRAM cell 104 is located between a local connection lines LI M1 and a Vss landing pad Vss M1 (or bit line landing pad BL M1 or bit line bar landing pad BLB M1) along the x direction. As such, the location of the first vias V1 that connect to the word line metals WL-1 M2 and WL-2 M2 are also changed accordingly (see FIG. 5B).

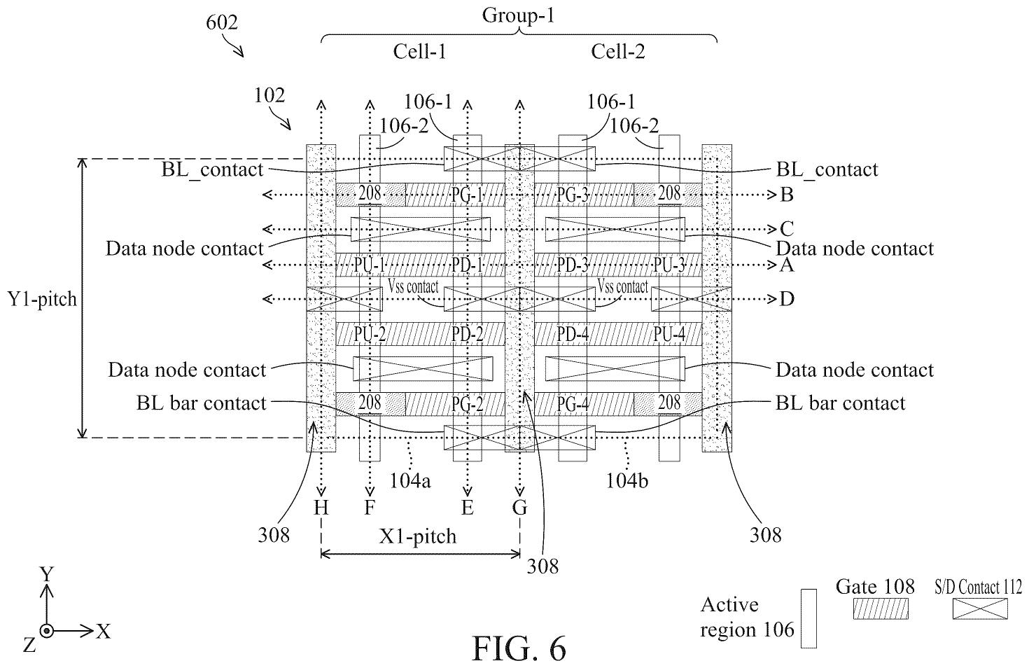

FIG. 6 illustrates a top view device layout 602 of an SRAM array 102 having two adjacent memory cells 104. In the present embodiment, FIG. 6 illustrates cell-1 and cell-2 (corresponding to SRAM cells 104a and 104b) of group-1 in FIG. 3. Note that FIG. 6 additionally illustrates lines A-H that cut across various regions of the device layout 602. The SRAM array 102 at the lines A-H is described with respect to FIGS. 7A, 7B, 7C-1, 7C-2, 7D-1, 7D-2, 7E-1, 7E-2, 7F-1, 7F-2, 7G, and 7H.

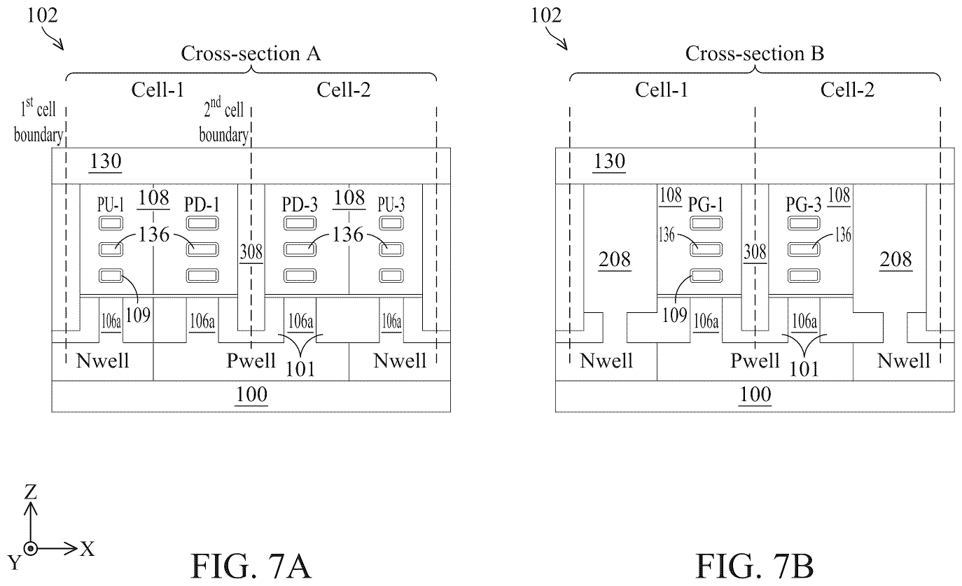

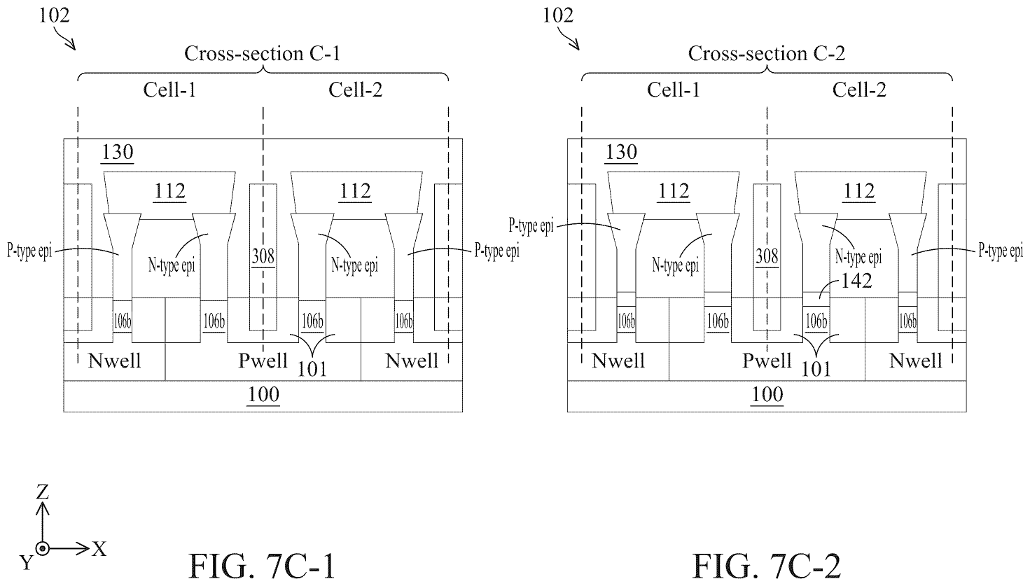

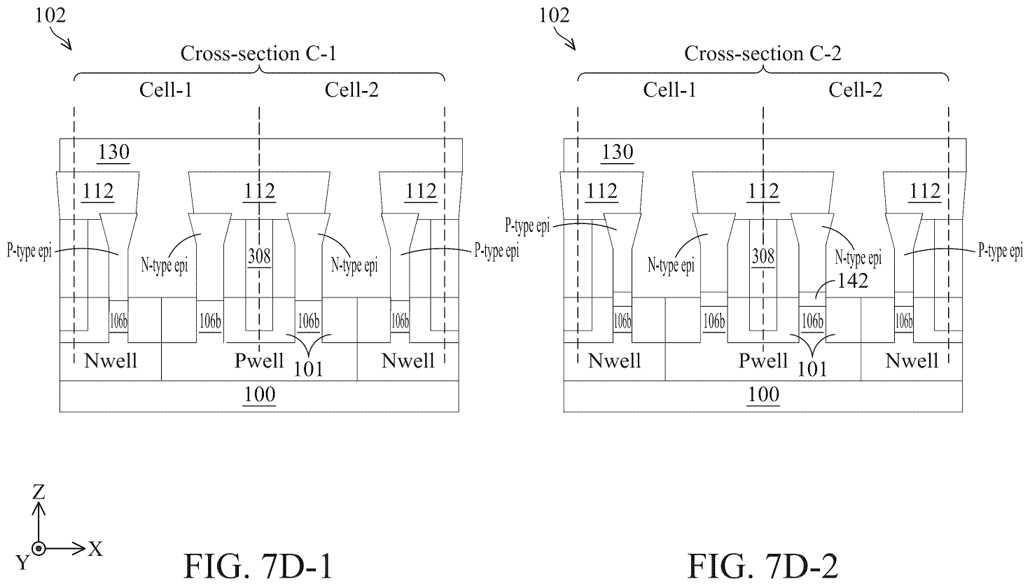

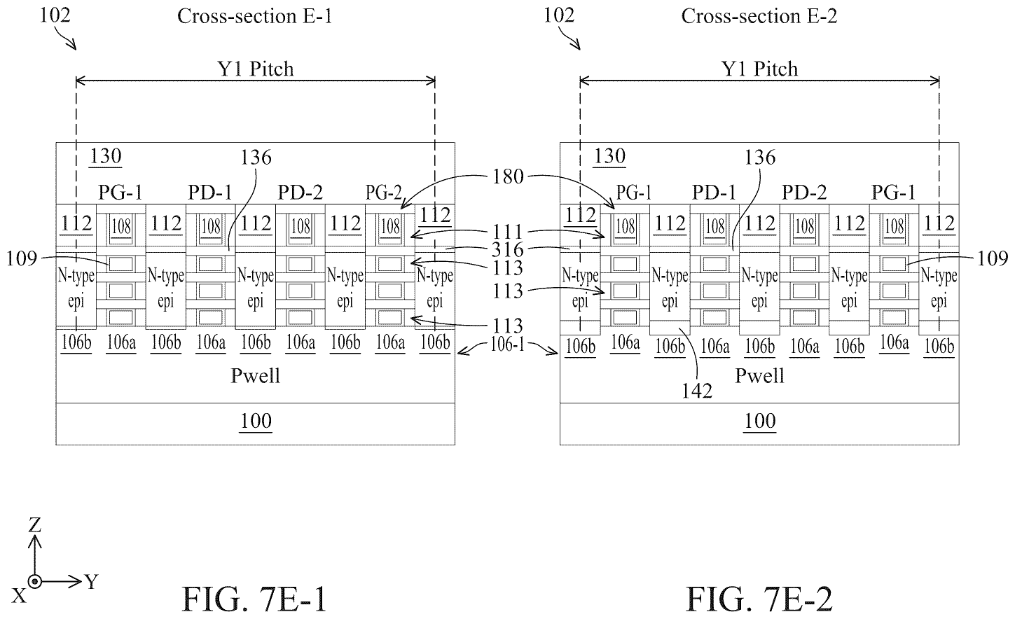

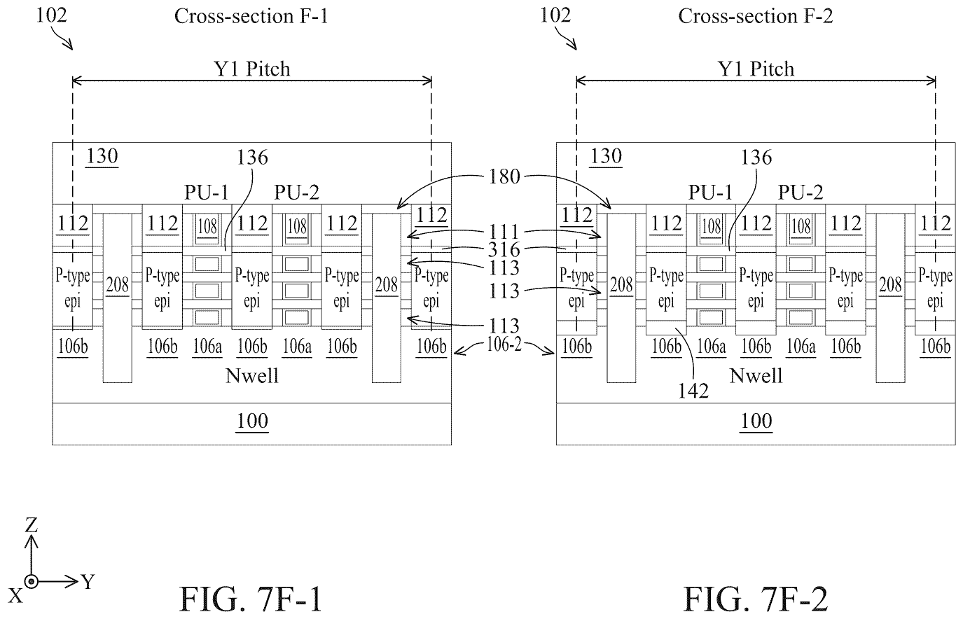

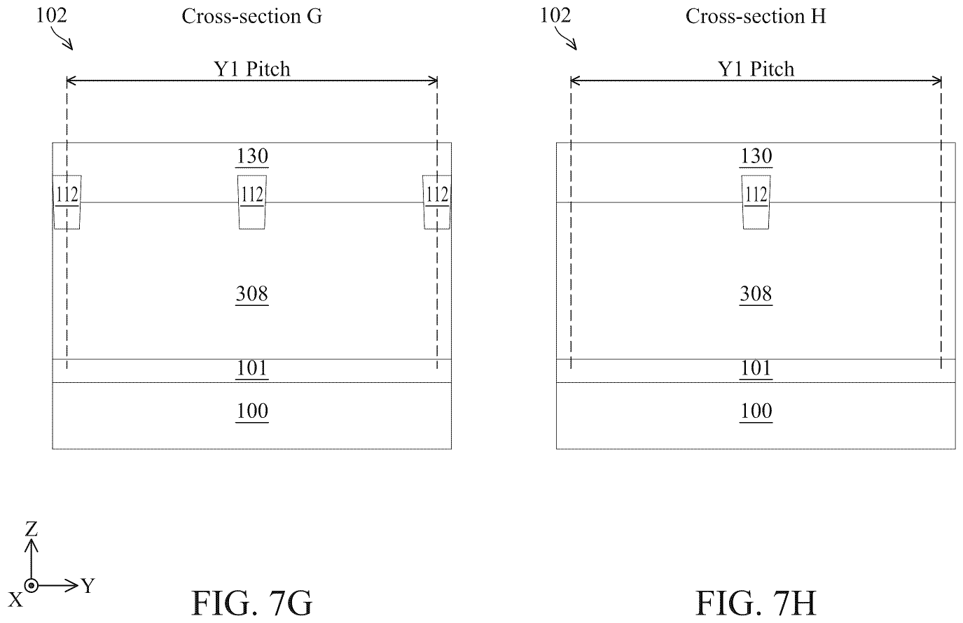

FIG. 7A illustrates a cross-sectional view of an SRAM array 102 cut along the line A in FIG. 6. This cross-sectional view is referred to as cross-section A. Cross-section A cuts across a gate 108 along the x direction, and the gate 108 is for pull-down and pull-up transistors (i.e., PU-1, PD-1, PD-3, PU-3). As shown in cross-section A, the SRAM array 102 includes a substrate 100. The substrate 100 may be a silicon (Si) substrate, or a substrate having other semiconductor materials such as germanium (Ge), silicon carbide (SiC), silicon germanium (SiGe), or diamond. The substrate 100 may include Nwells doped with n-type dopants for forming p-type transistor devices (e.g., pull-up transistors PU-1 and PU-3) and Pwells doped with p-type dopants for forming n-type devices (e.g., pull-down transistors PD-1 and PD-3). The Nwells and Pwells may have a depth ranging between about 50 nm to about 300 nm.

Still referring to FIG. 7A, cross-section A illustrates channel regions 106a of the active regions 106 protruding from the substrate 100. The active regions 106 may include Si, Ge, SiGe, SiC, gallium arsenide (GaAs), gallium nitride (GaN), carbon (C), indium (In), or combinations thereof. The active regions 106 (including channel regions 106a) are separated from each other by an isolation structure 101. The isolation structure 101 provides isolation between adjacent fin active regions 106 and may be a shallow trench isolation (STI) layer. The isolation structure 101 may include silicon oxide, silicon oxynitride, fluorine-doped silicate glass (FSG), a low-k dielectric, combinations thereof, and/or other suitable materials. In the present embodiment, the isolation structure 101 is disposed over the substrate 100, and each of the active regions 106 protrudes from the substrate 100 to above the isolation structure 101.

Still referring to FIG. 7A, for gate-all around devices, the channel regions 106a may include transistor channels 136 completely wrapped around by gates 108 (as shown). For fin devices, the channel regions 106a may include a single fin channel wrapped around by gates 108 on three sides (not shown). The gates 108 include metal gate portions that wrap around gate dielectric layers 109, and the gate dielectric layers 109 wrap around the channel regions 106a. The gate dielectric layers 109 may include a high-k dielectric material such as a material having a dielectric constant greater than silicon oxide (k≈3.9). The high-k dielectric material may include a metal oxide such as hafnium oxide, zirconium oxide, aluminum oxide, or a combination thereof. In an embodiment, The metal gate portions of the gates 108 may include different metal materials for wrapping around transistor channels 136 for p-type devices (e.g., PU-1 and PU-3) and for n-type devices (PD-1 and PD-3).

Still referring to FIG. 7A, the gate-cut dielectric lines 308 cut and completely penetrate through the gates 108 at the cell boundaries (e.g., 1st cell boundary, 2nd cell boundary, etc.). The gate-cut dielectric lines 308 isolate gates 108 between different respective memory cells 104. In some embodiment, the gate-cut dielectric lines 308 further penetrate into the isolation structure 101, where bottom portions of the gate-cut dielectric lines 308 are embedded in the isolation structure 101. The gate-cut dielectric lines 308 may include a single dielectric layer or multiple dielectric layers, and the single or multiple dielectric layers may include SiO₂, SiOC, SiON, SiOCN, carbon content oxide, nitrogen content oxide, metal oxide dielectric, HfO₂, TaO₂, TiO₂, ZrO₂, AlO₃, Y₂O₃, or combinations thereof. In an embodiment, the gate-cut dielectric lines 308 and the isolation structure 101 include different dielectric materials (e.g., the gate-cut dielectric lines 308 include silicon oxynitride and the isolation structure 101 includes silicon oxide). In the embodiment shown, top surfaces of the gate-cut dielectric lines 308 and the gates 108 are substantially coplanar after a planarization process. Also as shown, an interlayer dielectric (ILD) layer 130 may be disposed over top surfaces of the gate-cut dielectric lines 308 and the gates 108. The ILD layer 130 may include a dielectric material that includes for example, silicon oxide, silicon nitride, silicon oxynitride, tetraethoxysilane (TEOS) formed oxide, Phosphosilicate Glass (PSG), Boron-Doped Phosphosilicate Glass (BPSG), low-k dielectric material, other suitable dielectric material, or combinations thereof.

FIG. 7B illustrates a cross-sectional view of an SRAM array 102 cut along the line B in FIG. 6. This cross-sectional view is referred to as cross-section B. Cross-section B is similar to cross-section A, except that cross-section B cuts across a gate 108 along the x direction for pass-gate transistors (i.e., PG-1, PG-3). In cross-section B, the gates 108 includes metal gate portions that wrap around transistor channels 136 and dielectric gate portions 208 adjacent the metal gate portions. The metal gate portions may be simply referred to as metal gates, and the dielectric gate portions 208 may be simply referred to as dielectric gates 208. As shown, the dielectric gates 208 are sandwiched between side surfaces of the gate-cut dielectric lines 308 and the metal gates. The dielectric gates 208 may directly contact side surfaces of the gate-cut dielectric lines 308 and the metal gates. The dielectric gates 208 may have top surfaces that are substantially coplanar with top surfaces of the gate-cut dielectric lines 308 and the metal gate portions of the gates 108.

Still referring to FIG. 7B, and comparing with FIG. 7A, the dielectric gates 208 completely penetrate through channel regions 106a for pull-up transistors (e.g., PU-1 and PU-3). In effect, the dielectric gates 208 replace the respective channel regions 106a and act as an active region isolation along the y direction (see FIG. 6). The dielectric gates 208 thereby form separate active regions 106 for pull-up transistors of different memory cells 104. In an embodiment, the dielectric gates 208 completely penetrates through the isolation structure 101 to land on a top surface of the substrate 100. As such, the bottom surface of the dielectric gates 208 may be substantially coplanar with the bottom surface of the isolation structure 101. As shown, bottom surfaces of the dielectric gates 208 may be below bottom surfaces of the gate-cut dielectric lines 308, and bottom surfaces of the gate-cut dielectric lines 308 may be below bottom surfaces of the metal gates of the gates 108. In an embodiment, the dielectric gates 208 have a vertical height that ranges between about 60 nm to about 300 nm. In an embodiment, the dielectric gates 208 may include SiO₂, SiOC, SiON, SiOCN, Si₃N₄, carbon content oxide, nitrogen content oxide, an air gap, or combinations thereof. In an embodiment, the dielectric gates 208 and the gate-cut dielectric lines 308 include different dielectric materials (e.g., the dielectric gates 208 includes silicon oxide and the gate-cut dielectric lines 308 include silicon oxynitride).

FIG. 7C-1 illustrates a cross-sectional view of an SRAM array 102 cut along the line C in FIG. 6. This cross-sectional view is referred to as cross-section C-1. Cross-section C-1 cuts across S/D contacts 112 along the x direction. Cross-section C-1 illustrates source/drain (S/D) regions 106b of the active regions 106 protruding from the substrate 100. The S/D regions 106b include epitaxial features, referred to in the drawings as p-type epi and/or n-type epi. The epitaxial features may be formed to have an expanding profile to form a widened shape over a top portion of the S/D regions 106b. The epitaxial features may be doped with n-type dopants for n-type epi and/or p-type dopants for p-type epi. In some embodiments, for n-type transistors, epitaxial features include silicon and can be doped with carbon, phosphorous, arsenic, other n-type dopant, or combinations thereof (for example, forming Si:C epitaxial source/drain features, Si:P epitaxial source/drain features, or Si:C:P epitaxial source/drain features). In some embodiments, for p-type transistors, epitaxial features include silicon germanium or germanium and can be doped with boron, other p-type dopant, or combinations thereof (for example, forming Si:Ge:B epitaxial source/drain features).

Still referring to FIG. 7C-1, S/D contacts 112 land on epitaxial features of the S/D regions 106b. In this cross-sectional view, the S/D contacts 112 extend in the x direction between gate-cut dielectric lines 308 and land on adjacent epitaxial features of opposite types (i.e., n-type epi and p-type epi). Note that in this embodiment, the gate-cut dielectric lines 308 are disposed directly between adjacent S/D contacts 112 of different memory cells 104. The gate-cut dielectric lines 308 provide isolation between epitaxial features (e.g., n-type or p-type epi) of different memory cells 104, thereby preventing any unwanted epitaxial merging or bridging. Although not shown, due to having gate-cut dielectric lines 308, the epitaxial features (e.g., n-type epi or p-type epi) may be grown such that they expand to directly contact and touch side surfaces of the gate-cut dielectric lines 308. As shown, a top surface of the S/D contacts 112 is above a top surface of the gate-cut dielectric lines 308, and the top surface of the gate-cut dielectric lines 308 is above a top surface of the epitaxial features. An interlayer dielectric (ILD) layer 130, such as the one previously described, may be disposed over and embed the epitaxial features of the S/D regions 106b, the S/D contacts 112, and the gate-cut dielectric lines 308.

FIG. 7C-2 illustrates a cross-sectional view of an SRAM array 102 cut along the line C in FIG. 6. This cross-sectional view is referred to as cross-section C-2. Cross-section C-2 is the same as cross-section C-1, except that the S/D regions 106b may include S/D bottom dielectric layers 142. The S/D bottom dielectric layers 142 are disposed under the epitaxial features of the S/D regions 106b, and the S/D bottom dielectric layers 142 provide isolation between the doped epitaxial features and the substrate 100 (or well regions thereof, e.g., Nwell and Pwell). Such isolation improves transistor operation by insulating first type dopants in the well regions from second type dopants in the epitaxial features, where the first type and the second type dopants are opposite type dopants.

FIG. 7D-1 illustrates a cross-sectional view of an SRAM array 102 cut along the line D in FIG. 6. This cross-sectional view is referred to as cross-section D-1. Cross-section D-1 is like cross-section C-1 and also cuts across S/D contacts 112 along the x direction. The difference is that in cross-section D-1, the S/D contacts 112 extend in the x direction across gate-cut dielectric lines 308 (i.e., cell boundaries) and land on adjacent epitaxial features of same types (i.e., n-type and n-type epi or p-type and p-type epi). The S/D contacts 112 also land on the gate-cut dielectric lines 308. Note that in this embodiment, the gate-cut dielectric lines 308 are disposed directly under S/D contacts 112 between adjacent epitaxial features of different memory cells 104. As shown, a top surface of the gate-cut dielectric lines 308 may be below a top surface of the epitaxial features. An interlayer dielectric (ILD) layer 130, such as the one previously described, may be disposed over and embed the epitaxial features of the S/D regions 106b, the S/D contacts 112, and the gate-cut dielectric lines 308.

FIG. 7D-2 illustrates a cross-sectional view of an SRAM array 102 cut along the line D in FIG. 6. This cross-sectional view is referred to as cross-section D-2. Cross-section D-2 is the same as cross-section D-1, except that the S/D regions 106b may include S/D bottom dielectric layers 142. The S/D bottom dielectric layers 142 are disposed under the epitaxial features of the S/D regions 106b, and the S/D bottom dielectric layers 142 provide isolation between the doped epitaxial features and the substrate 100 (or well regions thereof, e.g., Nwell and Pwell). Such isolation improves transistor operation by insulating first type dopants in the well regions from second type dopants in the epitaxial features, where the first type and the second type dopants are opposite type dopants.

FIG. 7E-1 illustrates a cross-sectional view of an SRAM array 102 cut along the line E in FIG. 6. This cross-sectional view is referred to as cross-section E-1. Cross-section E-1 cuts across an n-type active region 106-1 along the y direction, and the n-type active region 106-1 forms pull-down and pass-gate transistors (i.e., PG-1, PD-1, PD-2, PG-2) over a Pwell over a substrate 100. Cross-section E-1 illustrates a y1 pitch corresponding to a cell height of a memory cell 104. The y1 pitch encompasses a continuous n-type active region 106-1 extending in the y direction. The n-type active region 106-1 includes channel regions 106a and S/D regions 106b adjacent the channel regions 106a. The y1 pitch further encompasses four gates 108 (or specifically metal gate portions of the gates 108) over the channel regions 106a. The y1 pitch further encompasses n-type epi as part of (or disposed over) the S/D regions 106b. In the embodiment shown, each of the gates 108 are metal gates, and the metal gates include gate stacks having gate dielectric layers 109 wrapping around transistor channels 136 and gate electrodes wrapping around the gate dielectric layers 109. The metal gates have top portions over the topmost transistor channel 136 and bottom portions below the topmost transistor channel 136. The top portions are surrounded by gate spacers 111 and the bottom portions are surrounded by inner spacers 113. The inner spacers 113 are disposed vertically between transistor channels 136. S/D contacts 112 are disposed over the epitaxial features of the S/D regions 106b (i.e., n-type epi) and may be adjacent to the gate spacers 111. In an embodiment, silicide features 316 are vertically disposed between the epitaxial features and the S/D contacts 112 for improving surface contact. In an embodiment, gate caps 180 may be disposed over the gates 108 and the gate spacers 111. The gate caps 180 may have top surfaces substantially coplanar with top surfaces of the S/D contacts 112. The gate spacers 111, the inner spacers 113, and the gate caps 180 may be formed of any suitable dielectric materials. An interlayer dielectric (ILD) layer 130, such as the one previously described, may be disposed over the S/D contacts 112, and the gate caps 180.

FIG. 7E-2 illustrates a cross-sectional view of an SRAM array 102 cut along the line E in FIG. 6. This cross-sectional view is referred to as cross-section E-2. Cross-section E-2 is the same as cross-section E-1, except that the S/D regions 106b may include S/D bottom dielectric layers 142. The S/D bottom dielectric layers 142 are disposed under the epitaxial features of the S/D regions 106b, and the S/D bottom dielectric layers 142 provide isolation between the doped epitaxial features and the substrate 100 (or well regions thereof, e.g., Nwell and Pwell). Such isolation improves transistor operation by insulating first type dopants in the well regions from second type dopants in the epitaxial features, where the first type and the second type dopants are opposite type dopants.

FIG. 7F-1 illustrates a cross-sectional view of an SRAM array 102 cut along the line F in FIG. 6. This cross-sectional view is referred to as cross-section F-1. Cross-section F-1 is similar to cross-section E-1, except that cross-section F-1 cuts a p-type active region 106-2 along the y direction, and the p-type active region 106-2 forms pull-up transistors (i.e., PU-1, PU-2) over an Nwell over the substrate 100. As such, p-type epi is formed in or over the S/D regions 106b instead of n-type epi. Further, in cross-section 7F-1, there are two dielectric gates 208 that penetrate through and replace channel regions 106a that are adjacent the channel regions 106a of the pull-up transistors PU-1 and PU-2. These dielectric gates 208 sandwich the gates 108 (i.e., metal gates) of the pull-up transistors PU-1 and PU-2. Note that the dielectric gates 208 and the gates 108 (i.e., metal gates) may have substantially same widths along the y direction. In the embodiment shown, gate caps 180 may be disposed on top surfaces of the dielectric gates 208.

FIG. 7F-2 illustrates a cross-sectional view of an SRAM array 102 cut along the line F in FIG. 6. This cross-sectional view is referred to as cross-section F-2. Cross-section F-2 is the same as cross-section F-1, except that the S/D regions 106b may include S/D bottom dielectric layers 142. The S/D bottom dielectric layers 142 are disposed under the epitaxial features of the S/D regions 106b, and the S/D bottom dielectric layers 142 provide isolation between the doped epitaxial features and the substrate 100 (or well regions thereof, e.g., Nwell and Pwell). Such isolation improves transistor operation by insulating first type dopants in the well regions from second type dopants in the epitaxial features, where the first type and the second type dopants are opposite type dopants.

FIG. 7G illustrates a cross-sectional view of an SRAM array 102 cut along the line G in FIG. 6. This cross-sectional view is referred to as cross-section G. Cross-section G cuts across a gate-cut dielectric line 308 along the y direction, and the gate-cut dielectric line 308 cuts through gates 108 to separate pull-down and pass-gate transistors in adjacent memory cells 104. In this cross-sectional view, the isolation structure 101 is disposed on the substrate 100, the gate-cut dielectric line 308 is disposed on the isolation structure 101, and the S/D contacts 112 are disposed on the gate-cut dielectric line 308. The S/D contacts 112 may partially penetrate into the gate-cut dielectric line 308. Two of the S/D contacts 112 may be on cell boundaries of the SRAM array 102, and one of the S/D contacts may be in between cell boundaries of the SRAM array 102.

FIG. 7H illustrates a cross-sectional view of an SRAM array 102 cut along the line H in FIG. 6. This cross-sectional view is referred to as cross-section H. Cross-section G cuts across another gate-cut dielectric line 308 along the y direction, and this gate-cut dielectric line 308 cuts through gates 108 to separate pull-up transistors in adjacent memory cells 104. In this cross-sectional view, the isolation structure 101 is disposed on the substrate 100, the gate-cut dielectric line 308 is disposed on the isolation structure 101, and a S/D contact is disposed on the gate-cut dielectric line 308. The S/D contacts 112 may partially penetrate into the gate-cut dielectric line 308 and be in between cell boundaries of the SRAM array 102.

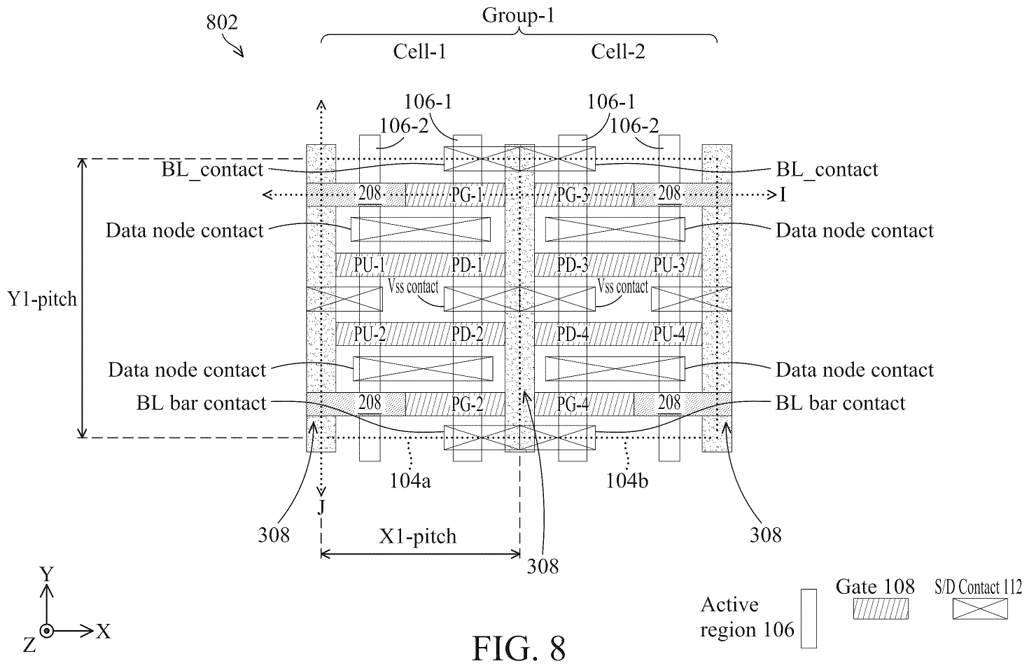

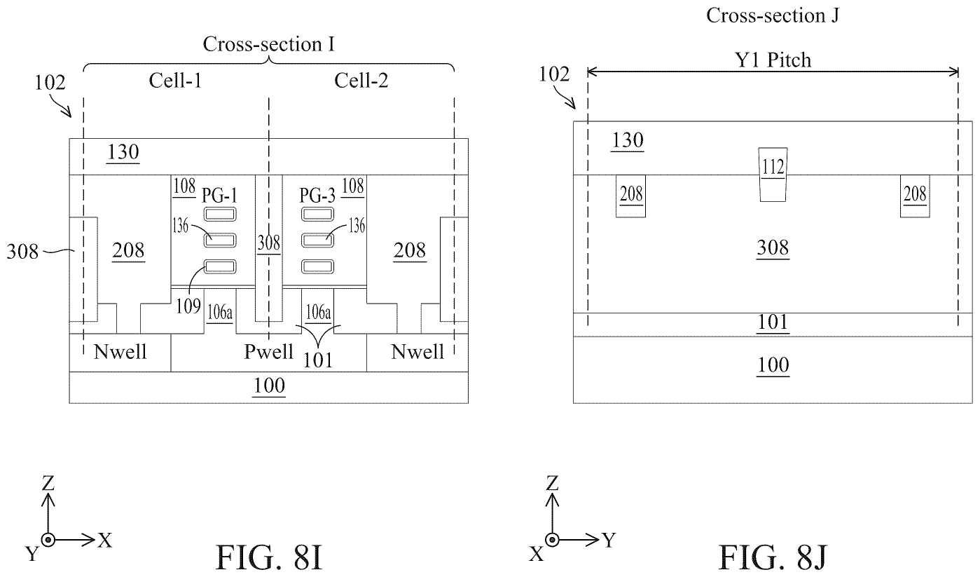

FIG. 8 illustrates a top view device layout 802 of an SRAM array 102 having two adjacent memory cells 104, according to another embodiment of the present disclosure. FIG. 8 resembles FIG. 6, and FIG. 8 likewise illustrates cell-1 and cell-2 (corresponding to SRAM cells 104a and 104b) of group-1 in FIG. 3. Note that FIG. 8 illustrates lines I and J that corresponds to the lines B and H, respectively, of FIG. 6. The SRAM array 102 at the lines I and J is described with respect to FIGS. 81 and 8J.

FIG. 8I illustrates a cross-sectional view of an SRAM array 102 cut along the line I in FIG. 8. This cross-sectional view is referred to as cross-section I. FIG. 8I resembles FIG. 7B, and the similar features will not be described again for the sake of brevity. The difference is that the dielectric gates 208 (or a portion thereof) may be disposed on top of adjacent gate-cut dielectric lines 308. In this embodiment, the dielectric gates 208 may be formed after forming the gate-cut dielectric lines 308. And when forming the dielectric gates 208, a top portion of the respective gate-cut dielectric lines 308 are partially etched such that the dielectric gates 208 are formed over the gate-cut dielectric lines 308.

FIG. 8J illustrates a cross-sectional view of an SRAM array 102 cut along the line J in FIG. 8. This cross-sectional view is referred to as cross-section J. FIG. 8J resembles FIG. 7H, and the similar features will not be described again for the sake of brevity. The difference is that the dielectric gates 208 (or a portion thereof) may be surrounded by the gate-cut dielectric line 308.

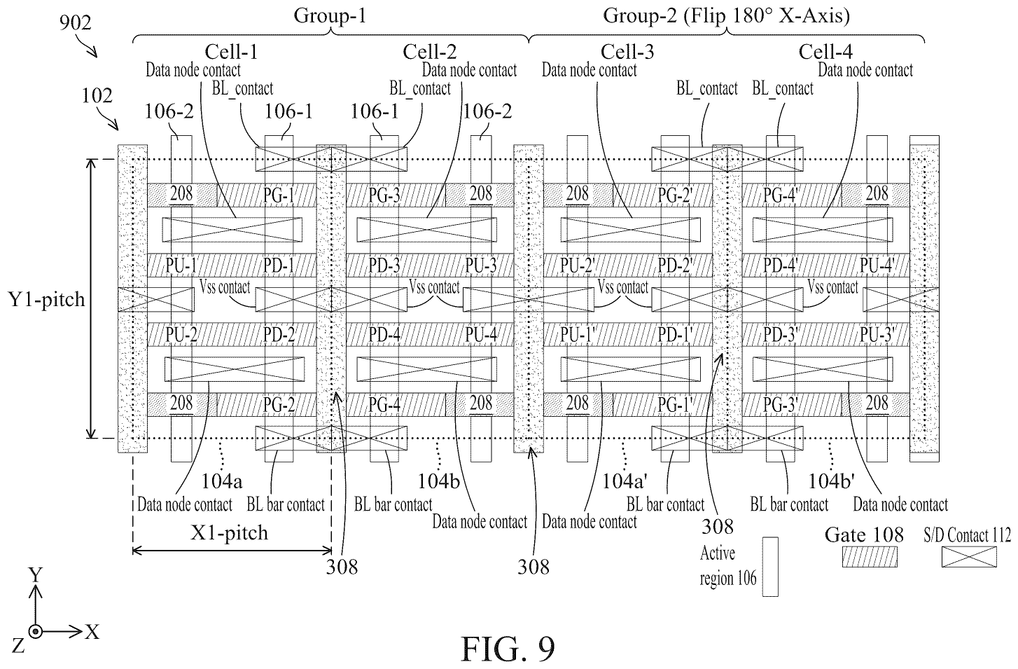

FIGS. 9-12 illustrate top view device layouts of SRAM arrays 102 corresponding to the circuit diagram of FIG. 2, according to additional embodiments of the present disclosure.

Referring now to FIG. 9, the device layout 902 is similar to the device layout 302 in FIG. 3, except that the transistors in group-2's cell-3 and cell-4 are oriented such that they do not mirror group-1 in the y axis (like in FIG. 3). Instead, they are flipped 180 degrees in the x axis compared to group-1. As shown, in this configuration, SRAM cell 104a′ now corresponds to cell-3 and SRAM cell 104b′ now corresponds to cell-4, whereas in the configuration of device layout 302 in FIG. 3, SRAM cell 104b′ corresponded to cell-3 and SRAM cell 104a′ corresponded to cell-4.

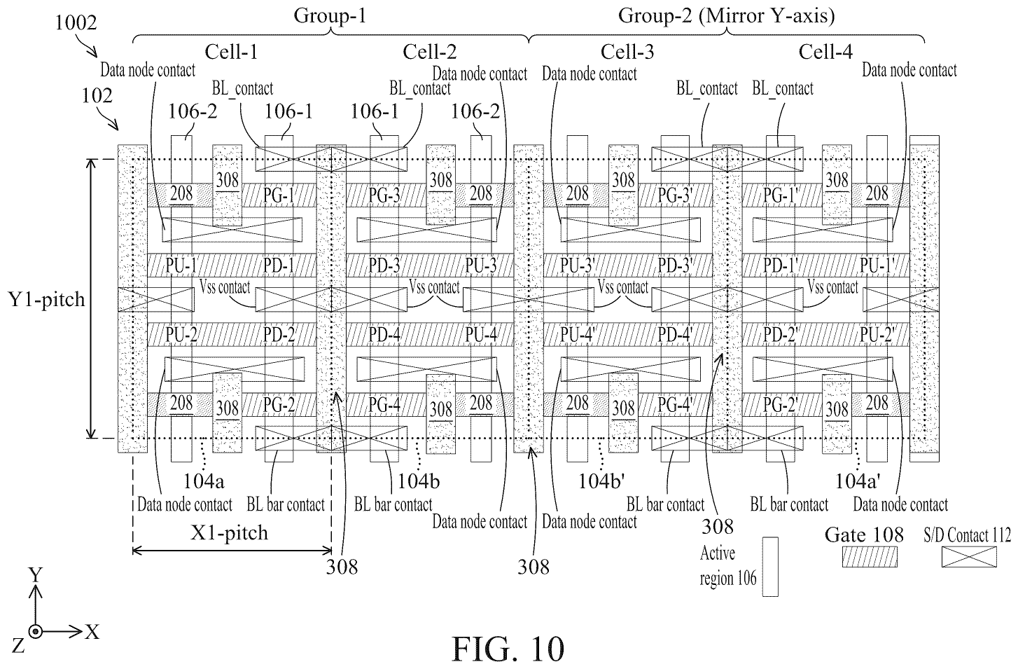

Referring now to FIG. 10, the device layout 1002 is similar to the device layout 302 in FIG. 3, except that there are extra gate-cut dielectric lines 308 located between the pass-gate transistors (e.g., PG-1, PG-2) and the dielectric gates 208. These extra gate-cut dielectric lines 308 do not continuously extend across memory cells 104 along the y direction (i.e., they do not cut through the gates 108 for the pull-down and pull-up transistors). These extra gate-cut dielectric lines 308 are helpful to prevent metal particles in the gates 108 for pass-gate transistors (e.g., PG-1, PG-2) from diffusing into the dielectric gate 208. Such diffusion may cause undesired coupling between diffused metal particles with surrounding features. In the present embodiment, the gate-cut dielectric lines 308 and the extra gate-cut dielectric lines 308 are formed after forming the dielectric gates 208.

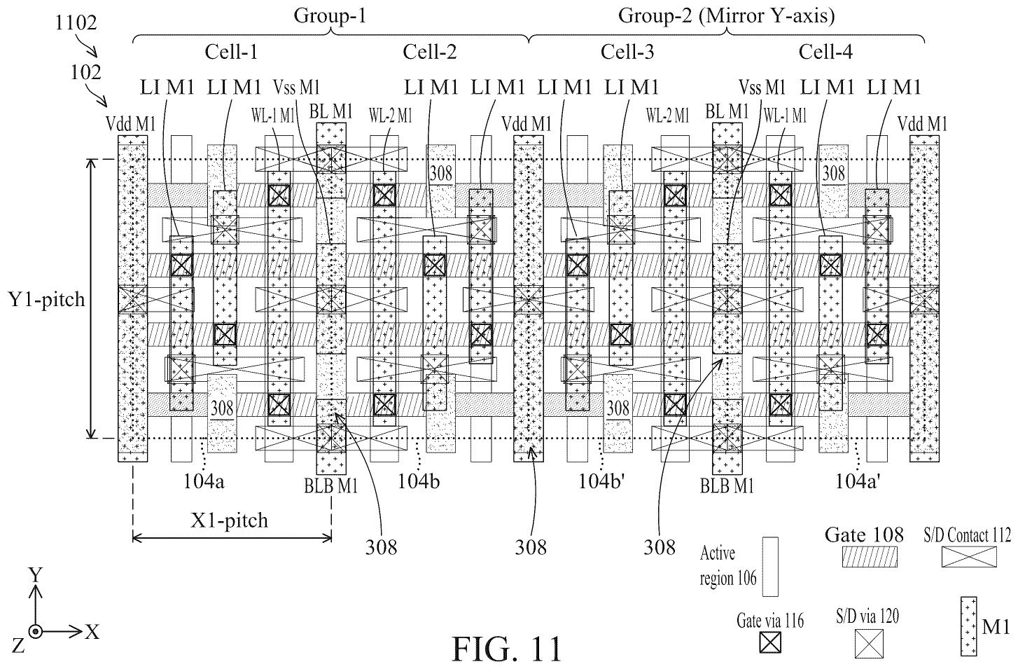

Referring now to FIG. 11, the device layout 1102 further shows gate vias 116, S/D vias 120, and first metal lines M1 over the device layout 1002 in FIG. 10. The device layout 1102 is similar to the device layout 502a in FIG. 5A previously described, except that due to the extra gate-cut dielectric lines 308, in an embodiment, some or all of the SRAM cells 104 (e.g., cell-2 and cell-4) may have their two local connection lines LI M1 flipped in position when compared with the device layout 502a in FIG. 5A.

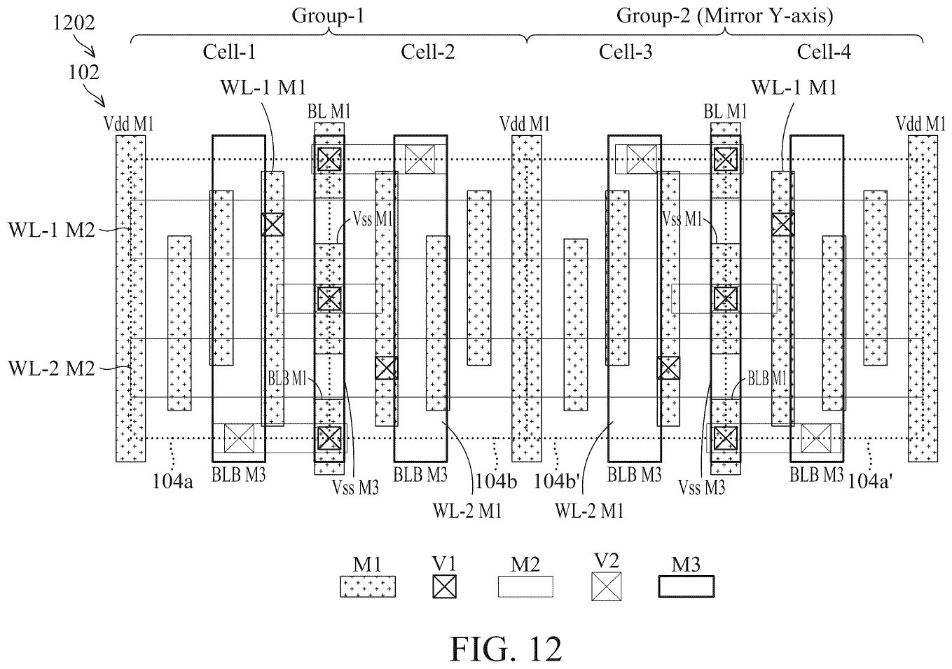

Referring now to FIG. 12, the device layout 1202 corresponds to the device layout 1102 in FIG. 11. FIG. 12 only shows the first metal lines M1 from FIG. 11 while the features disposed under it are filtered out for ease of view. FIG. 12 further shows first vias V1 landing on the first metal lines M1, second metal lines M2 landing on the first vias V1, second vias V2 landing on the second metal lines M2, and third metal lines M2 landing on the second vias V2. FIG. 12 include similar features as FIG. 5B, and the similar features will not be repeated again for the sake of brevity.

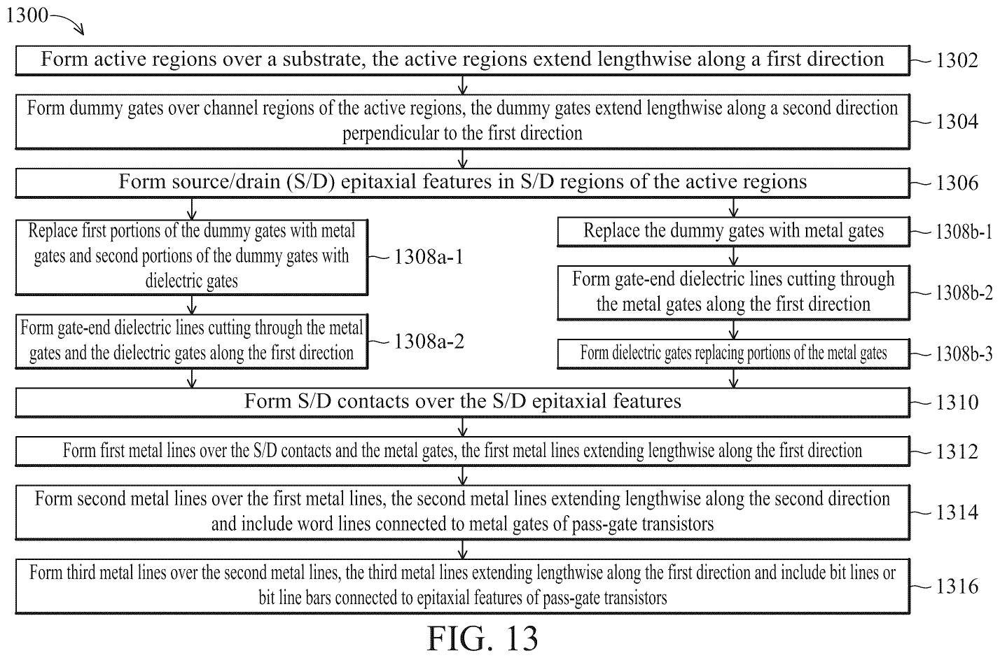

FIG. 13 illustrates a method 1300 of forming an SRAM array structure (e.g., SRAM array 102) having gate-end dielectric lines (e.g., gate-cut dielectric lines 308), according to an embodiment of the present disclosure. At operation 1302, the method 1300 forms active regions (e.g., active regions 106) over a substrate (e.g., substrate 100), the active regions extend lengthwise along a first direction (e.g., y direction). At operation 1304, the method 1300 forms dummy gates (not shown) over channel regions (e.g., channel regions 106a) of the active regions, the dummy gates extend lengthwise along a second direction (e.g., x direction) perpendicular to the first direction. The dummy gates may include polysilicon, amorphous silicon, or microcrystal silicon. At operation 1306, the method forms source/drain (S/D) epitaxial features (e.g., n-type and p-type epi) in S/D regions (e.g., S/D regions 106b) of the active regions.

Still referring to FIG. 13, the method 1300 may include two separate paths when forming gate structures (e.g., gates 108) and gate-end dielectric lines (e.g., gate-cut dielectric lines 308).

In a first path, the method 1300 at operation 1308a-1 replaces first portions of the dummy gates with metal gates (e.g., gate portions not part of dielectric gates) and second portions of the dummy gates with dielectric gates (e.g., dielectric gate portions 208). In an embodiment, the metal gate portions are first formed by a first patterning process, then the dielectric gate portions are formed by a second patterning process. In another embodiment, the dielectric gate portions are first formed by a first patterning process, then the metal gate portions are formed by a second patterning process. Thereafter, at operation 1308a-2, the method 1300 forms gate-end dielectric lines (e.g., gate-cut dielectric lines 308) cutting through the metal gates and the dielectric gates along the first direction. After a planarization process, the resulting gate structures may resemble those shown in FIG. 7B.

In a second path, the method 1300 at operation 1308b-1 replaces the dummy gates with metal gates. Thereafter, at operation 1308b-2, the method 1300 forms gate-end dielectric lines (e.g., gate-cut dielectric lines 308) cutting through the metal gates along the first direction. Thereafter, at operation 1308b-3, the method 1300 forms dielectric gates (e.g., dielectric gate portions 208) replacing portions of the metal gates. After a planarization process, the resulting gate structures may resemble those shown in FIG. 8I.

Still referring to FIG. 13, after forming various gate features (i.e., metal gates, dielectric gates, and gate-end dielectric lines), the method 1300 at operation 1310 forms S/D contacts (e.g., S/D contacts 112) over the S/D epitaxial features. At operation 1312, the method 1300 forms first metal lines (e.g., first metal lines M1) over the S/D contacts and the metal gates, the first metal lines extending lengthwise along the first direction. At operation 1314, the method 1300 forms second metal lines (e.g., second metal lines M2) over the first metal lines, the second metal lines extending lengthwise along the second direction and include word lines connected to metal gates of pass-gate transistors (e.g., PG-1, PG-2). At operation 1316, the method 1300 forms third metal lines (e.g., third metal lines M3) over the second metal lines, the third metal lines extending lengthwise along the first direction and include bit lines or bit line bars connected to epitaxial features of pass-gate transistors (e.g., PG-1, PG-2).

Although not limiting, the present disclosure offers advantages for SRAM cell structures. One example advantage is incorporating gate-end dielectric lines for uniform isolation between memory cells and for allowing S/D features to be formed until touching the gate-end dielectric lines. Another example advantage is incorporating dielectric gates for uniform isolation of pull-up transistors between memory cells. Another example advantage is sharing a bit lines and bit line bars across two memory cells and moving these bit signal lines into a higher metal layer for better metal spacing and distribution.

One aspect of the present disclosure pertains to a memory structure. The memory structure includes multiple memory cells, each of the memory cells includes two active regions extending lengthwise along a first direction and four gate structures extending lengthwise along a second direction perpendicular to the first direction. Each of the four gate structures extend across channel regions of the two active regions. The memory structure further includes a pair of gate-cut dielectric features extending lengthwise along the first direction at cell boundaries between each of the memory cells, each of the gate-cut dielectric features contacts the each of the four gate structures in each of the memory cells.

In an embodiment, the each of the memory cells is defined by a cell height along the first direction and a cell width along the second direction, and the cell height is greater than the cell width.

In a further embodiment, the cell height is a distance substantially equal to four times a distance between respective center lines of two adjacent gate structures along the first direction. The cell width is a distance between respective center lines of two adjacent gate-cut dielectric features along the second direction.

In an embodiment, the each of the memory cells includes: two pull-down transistors and two pass-gate transistors formed on a first active region of the two active regions, and two pull-up transistors formed on a second active region of the two active regions.

In a further embodiment, a first and a second memory cell of the multiple memory cells are adjacent to each other and share a bit-line contact and bit-line bar contact. The bit-line contact extends lengthwise over and across a gate-cut dielectric feature of the gate-cut dielectric features to land on source/drain (S/D) features of first pass-gate transistors in the first and second memory cells. The bit-line bar contact extends lengthwise across the gate-cut dielectric feature to land on source/drain (S/D) features of second pass-gate transistors in the first and second memory cells.

In an embodiment, in each of the memory cells: two of the four gate structures include dielectric gates extending across channel regions of a first active region of the two active regions, where the dielectric gates cut through the first active regions along the second direction and directly abut one of the gate-cut dielectric features, where the dielectric gates are directly adjacent to pull-up transistors formed on the first active region along the first direction.

In a further embodiment, in each of the memory cells: the gate-cut dielectric features, the dielectric gates, and metal gates of the four gate structures, are each formed over an isolation structure over a substrate, where the gate-cut dielectric features and the dielectric gates penetrate into the isolation structure and the dielectric gates penetrate deeper into the isolation structure than the gate-cut dielectric features.

In an embodiment, the memory structure further includes bit line metals electrically connected to source/drain (S/D) features of pass-gate transistors in the multiple memory cells, the pass-gate transistors are formed on an active region of the two active regions in each memory cell; and word line metals electrically connected to gates of the pass-gate transistors in the multiple memory cells. The bit line metals are global bit lines that continuously extend lengthwise along the first direction across a column of the multiple memory cells, the word line metals are global word lines that continuously extend lengthwise along the second direction across a row of the multiple memory cells. The bit line metals are disposed in a first metal layer, the word line metals are disposed in a second metal layer, and the first metal layer is above the second metal layer.

In an embodiment, in each of the memory cells, source/drain (S/D) features formed over the two active regions include epitaxial features that directly contact the gate-cut dielectric features.

In an embodiment, the gate-cut dielectric features and the gate structures have substantially coplanar top surfaces.

In an embodiment, the memory structure further includes a first metal layer having first metal lines extending lengthwise along the first direction, the first metal lines include local interconnects that electrically connect gates of different transistors in a memory cell together, source/drain (S/D) features of different transistors in a memory cell together, or gates and S/D features of different transistors in a memory cell together; a second metal layer having second metal lines extending lengthwise along the second direction, the second metal lines include word line metals that electrically connect gates of different pass-gate transistors in different memory cells together; and a third metal layer having third metal lines extending lengthwise along the first direction, the third metal lines include bit line and bit line bar metals that electrically connect sources of different pass-gate transistors in different memory cells together.

Another aspect of the present disclosure pertains to a memory structure. The memory structure includes a first memory cell spanning between a first and a second gate-cut dielectric line, the first and the second gate-cut dielectric lines extend lengthwise along a first direction; and a second memory cell spanning between the second gate-cut dielectric line and a third gate-cut dielectric line, the third gate-cut dielectric line extends lengthwise along the first direction. The first memory cell includes: first and second active regions over a substrate, the first and the second active regions extend lengthwise along the first direction, and first gate structures over channel regions of the first and second active regions, the first gate structures extend lengthwise along a second direction perpendicular to the first direction. The second memory cell includes: third and fourth active regions over the substrate, the third and the fourth active regions extend lengthwise along the first direction, and second gate structures over channel regions of the third and fourth active regions, the second gate structures extend lengthwise along the second direction. The second gate-cut dielectric line directly contacts side surfaces of the first and second gate structures.

In an embodiment, the first active region and the first gate structures form a first pass-gate transistor, a first pull-down transistor, a second pull-down transistor, and a second pass-gate transistor. The second active region and the first gate structures form a first pull-up transistor and a second pull-up transistor. The third active region and the second gate structures form a third pass-gate transistor, a third pull-down transistor, a fourth pull-down transistor, and a fourth pass-gate transistor. The fourth active region and the second gate structures form a third pull-up transistor and a fourth pull-up transistor.

In a further embodiment, the memory structure further includes source/drain (S/D) contacts over S/D regions of the first, second, third, and fourth active regions. The S/D contacts include a bit line contact landing on a source region of the first pass-gate transistor and the third pass-gate transistor, and a bit line bar contact landing on a source region of the second pass-gate transistor and the fourth pass-gate transistor. The bit line contact and the bit line bar contact land on a top surface of the second gate-cut dielectric line.

In a further embodiment, the first gate structures include first dielectric gate portions and first metal gate portions, where the first dielectric gate portions cut through the second active region to contact the first gate-cut dielectric line, where the first pull-up and the second pull-up transistors are sandwiched between the first dielectric gate portions. The second gate structures include second dielectric gate portions and second metal gate portions, where the second dielectric gate portions cut through the fourth active region to contact the third gate-cut dielectric line, where the third pull-up and the fourth pull-up transistors are sandwiched between the second dielectric gate portions.

In a further embodiment, the memory structure further includes: a first gate-cut feature disposed between the first pass-gate transistor and one of the first dielectric gate portions; a second gate-cut feature disposed between the second pass-gate transistor and another one of the first dielectric gate portions; a third gate-cut feature disposed between the third pass-gate transistor and one of the second dielectric gate portions; and a fourth gate-cut feature disposed between the fourth pass-gate transistor and another one of the second dielectric gate portions.

Another aspect of the present disclosure pertains to method of forming a memory device structure. The method includes forming active regions over a substrate, the active regions extend lengthwise along a first direction; forming dummy gates over channel regions of the active regions, the dummy gates extend lengthwise along a second direction perpendicular to the first direction; forming source/drain (S/D) epitaxial features in S/D regions of the active regions; replacing first portions of the dummy gates with metal gates and second portions of the dummy gates with dielectric gates; forming gate-end dielectric lines cutting through the metal gates and the dielectric gates along the first direction; and forming S/D contacts over the S/D epitaxial features.

In an embodiment, the replacing of the first portions and the second portions of the dummy gates includes: replacing the dummy gates with metal gates; and forming dielectric gates replacing portions of the metal gates, wherein the forming of the gate-end dielectric lines is performed after the forming of the dielectric gates.

In a further embodiment, the method further includes forming gate-cut features between the dielectric gates and the metal gates.

In an embodiment, the replacing of first portions and the second portions of the dummy gates includes: replacing the dummy gates with metal gates; and forming dielectric gates replacing portions of the metal gates, wherein the forming of the gate-end dielectric lines is performed before the forming of the dielectric gates.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A memory structure, comprising:
multiple memory cells, each of the memory cells includes two active regions extending lengthwise along a first direction and four gate structures extending lengthwise along a second direction perpendicular to the first direction, each of the four gate structures extend across channel regions of the two active regions; and
a pair of gate-cut dielectric features extending lengthwise along the first direction at cell boundaries between each of the memory cells, each of the gate-cut dielectric features contacts the each of the four gate structures in each of the memory cells.

2. The memory structure of claim 1,
wherein the each of the memory cells is defined by a cell height along the first direction and a cell width along the second direction, and the cell height is greater than the cell width.

3. The memory structure of claim 2,
wherein the cell height is a distance substantially equal to four times a distance between respective center lines of two adjacent gate structures along the first direction,
wherein the cell width is a distance between respective center lines of two adjacent gate-cut dielectric features along the second direction.

4. The memory structure of claim 1,
wherein the each of the memory cells includes:
two pull-down transistors and two pass-gate transistors formed on a first active region of the two active regions, and
two pull-up transistors formed on a second active region of the two active regions.

5. The memory structure of claim 4,
wherein a first and a second memory cell of the multiple memory cells are adjacent to each other and share a bit-line contact and bit-line bar contact,
wherein the bit-line contact extends lengthwise over and across a gate-cut dielectric feature of the gate-cut dielectric features to land on source/drain (S/D) features of first pass-gate transistors in the first and second memory cells,
wherein the bit-line bar contact extends lengthwise across the gate-cut dielectric feature to land on source/drain (S/D) features of second pass-gate transistors in the first and second memory cells.

6. The memory structure of claim 1,
wherein in each of the memory cells:
two of the four gate structures include dielectric gates extending across channel regions of a first active region of the two active regions,
wherein the dielectric gates cut through the first active regions along the second direction and directly abut one of the gate-cut dielectric features,
wherein the dielectric gates are directly adjacent to pull-up transistors formed on the first active region along the first direction.

7. The memory structure of claim 6,
wherein in each of the memory cells:
the gate-cut dielectric features, the dielectric gates, and metal gates of the four gate structures, are each formed over an isolation structure over a substrate,
wherein the gate-cut dielectric features and the dielectric gates penetrate into the isolation structure and the dielectric gates penetrate deeper into the isolation structure than the gate-cut dielectric features.

8. The memory structure of claim 1, further comprising:
bit line metals electrically connected to source/drain (S/D) features of pass-gate transistors in the multiple memory cells, the pass-gate transistors are formed on an active region of the two active regions in each memory cell; and
word line metals electrically connected to gates of the pass-gate transistors in the multiple memory cells,
wherein the bit line metals are global bit lines that continuously extend lengthwise along the first direction across a column of the multiple memory cells, the word line metals are global word lines that continuously extend lengthwise along the second direction across a row of the multiple memory cells,
wherein the bit line metals are disposed in a first metal layer, the word line metals are disposed in a second metal layer, and the first metal layer is above the second metal layer.

9. The memory structure of claim 1,
wherein in each of the memory cells, source/drain (S/D) features formed over the two active regions include epitaxial features that directly contact the gate-cut dielectric features.

10. The memory structure of claim 1, wherein the gate-cut dielectric features and the gate structures have substantially coplanar top surfaces.

11. The memory structure of claim 1, further comprising:
a first metal layer having first metal lines extending lengthwise along the first direction, the first metal lines include local interconnects that electrically connect gates of different transistors in a memory cell together, source/drain (S/D) features of different transistors in a memory cell together, or gates and S/D features of different transistors in a memory cell together;
a second metal layer having second metal lines extending lengthwise along the second direction, the second metal lines include word line metals that electrically connect gates of different pass-gate transistors in different memory cells together; and
a third metal layer having third metal lines extending lengthwise along the first direction, the third metal lines include bit line and bit line bar metals that electrically connect sources of different pass-gate transistors in different memory cells together.

12. A memory structure, comprising:
a first memory cell spanning between a first and a second gate-cut dielectric line, the first and the second gate-cut dielectric lines extend lengthwise along a first direction; and
a second memory cell spanning between the second gate-cut dielectric line and a third gate-cut dielectric line, the third gate-cut dielectric line extends lengthwise along the first direction,
wherein the first memory cell includes:
first and second active regions over a substrate, the first and the second active regions extend lengthwise along the first direction, and
first gate structures over channel regions of the first and second active regions, the first gate structures extend lengthwise along a second direction perpendicular to the first direction,
wherein the second memory cell includes:
third and fourth active regions over the substrate, the third and the fourth active regions extend lengthwise along the first direction, and
second gate structures over channel regions of the third and fourth active regions, the second gate structures extend lengthwise along the second direction,
wherein the second gate-cut dielectric line directly contacts side surfaces of the first and second gate structures.

13. The memory structure of claim 12,
wherein the first active region and the first gate structures form a first pass-gate transistor, a first pull-down transistor, a second pull-down transistor, and a second pass-gate transistor,
wherein the second active region and the first gate structures form a first pull-up transistor and a second pull-up transistor,
wherein the third active region and the second gate structures form a third pass-gate transistor, a third pull-down transistor, a fourth pull-down transistor, and a fourth pass-gate transistor,
wherein the fourth active region and the second gate structures form a third pull-up transistor and a fourth pull-up transistor.

14. The memory structure of claim 13, further comprising:
source/drain (S/D) contacts over S/D regions of the first, second, third, and fourth active regions, the S/D contacts include:
a bit line contact landing on a source region of the first pass-gate transistor and the third pass-gate transistor, and
a bit line bar contact landing on a source region of the second pass-gate transistor and the fourth pass-gate transistor,
wherein the bit line contact and the bit line bar contact land on a top surface of the second gate-cut dielectric line.

15. The memory structure of claim 13,
wherein the first gate structures include first dielectric gate portions and first metal gate portions, wherein the first dielectric gate portions cut through the second active region to contact the first gate-cut dielectric line, wherein the first pull-up and the second pull-up transistors are sandwiched between the first dielectric gate portions,
wherein the second gate structures include second dielectric gate portions and second metal gate portions, wherein the second dielectric gate portions cut through the fourth active region to contact the third gate-cut dielectric line, wherein the third pull-up and the fourth pull-up transistors are sandwiched between the second dielectric gate portions.

16. The memory structure of claim 15, further comprising:
a first gate-cut feature disposed between the first pass-gate transistor and one of the first dielectric gate portions;
a second gate-cut feature disposed between the second pass-gate transistor and another one of the first dielectric gate portions;
a third gate-cut feature disposed between the third pass-gate transistor and one of the second dielectric gate portions; and
a fourth gate-cut feature disposed between the fourth pass-gate transistor and another one of the second dielectric gate portions.

17. A method of forming a memory device structure, comprising:
forming active regions over a substrate, the active regions extend lengthwise along a first direction;
forming dummy gates over channel regions of the active regions, the dummy gates extend lengthwise along a second direction perpendicular to the first direction;
forming source/drain (S/D) epitaxial features in S/D regions of the active regions;
replacing first portions of the dummy gates with metal gates and second portions of the dummy gates with dielectric gates;
forming gate-end dielectric lines cutting through the metal gates and the dielectric gates along the first direction; and
forming S/D contacts over the S/D epitaxial features.

18. The method of claim 17, wherein the replacing of the first portions and the second portions of the dummy gates includes:
replacing the dummy gates with metal gates; and
forming dielectric gates replacing portions of the metal gates, wherein the forming of the gate-end dielectric lines is performed after the forming of the dielectric gates.

19. The method of claim 18, further comprising:
forming gate-cut features between the dielectric gates and the metal gates.

20. The method of claim 17, wherein the replacing of first portions and the second portions of the dummy gates includes:
replacing the dummy gates with metal gates; and
forming dielectric gates replacing portions of the metal gates, wherein the forming of the gate-end dielectric lines is performed before the forming of the dielectric gates.
